(19) United States
(12) Patent Application Publication
(10) Pub. No.: US 2025/0374595 A1
(43) Pub. Date: Dec. 4, 2025

(54) SEMICONDUCTOR DEVICE AND METHOD FOR FORMING THE SAME

(71) Applicant: Vanguard International Semiconductor Corporation, Hsinchu (TW)

(72) Inventors: Wen-Shan LEE, Hsinchu City (TW); Chung-Yeh LEE, Xinpu Township (TW); Fu-Hsin CHEN, Zhudong Township (TW)

(73) Assignee: Vanguard International Semiconductor Corporation, Hsinchu (TW)

(21) Appl. No.: 18/679,834

(22) Filed: May 31, 2024

(51) Int. Cl. H01L 29/78; H01L 29/16; H01L 29/417; H01L 29/66

(52) U.S. Cl. CPC H10D 30/668; H10D 12/031; H10D 30/611; H10D 62/8325; H10D 64/256

(57) ABSTRACT

A semiconductor device and a method for forming the same are provided. The semiconductor device includes a silicon carbide substrate, an epitaxial layer, a first electrode, a separated conductive structure and a source metal layer. The epitaxial layer is disposed on a top surface of the silicon carbide substrate. The first electrode is disposed in the epitaxial layer in the first region of the silicon carbide substrate and extends in a first direction. The separated conductive structure is disposed in the epitaxial layer in the first region. The first conductive feature and the second conductive feature of the separated conductive structure are located on opposite sidewalls of the first electrode. The source metal layer is disposed on the epitaxial layer in the first region. The source metal layer covers and is electrically connected to the first conductive feature, the second conductive feature and the first electrode.

### BACKGROUND OF THE INVENTION

### Field of the Invention

The present disclosure relates to a semiconductor device and a method for forming the same, and, in particular, to a power transistor device having a Schottky diode and a method for forming the same.

### Description of the Related Art

The semiconductor industry continues to improve the integration density of different electronic components, thereby allowing more components to be integrated in a given area by continuing to reduce the minimum component size. For example, trench gate metal-oxide-semiconductor field effect transistors (MOSFETs), which are widely used in power switches, use a vertical structure design to increase functional density by reducing cell pitch. A trench gate MOSFET uses the back side of the chip as a drain electrode, and forms the source electrodes and the gate electrodes of multiple transistors on the front side of the chip. Therefore, the driving current flows from the horizontal direction to the vertical direction. A trench gate MOSFET also enables the semiconductor device to achieve a high reverse withstand voltage and low on-resistance.

However, as the functional density requirements on semiconductor devices continue to increase, the complexity of integrated components in the semiconductor devices and methods for forming semiconductor devices also increases. In addition, those electronic characteristics that have performance trade-offs need careful consideration. Although existing semiconductor devices are generally suitable and sufficient for their intended purposes, they have not been entirely satisfactory in all respects.

### BRIEF SUMMARY OF THE INVENTION

An embodiment of the disclosure provides a semiconductor device. The semiconductor device includes a silicon carbide substrate, an epitaxial layer, a first electrode, a separated conductive structure and a source metal layer. The silicon carbide substrate has a first region and a first conductivity type. The epitaxial layer is disposed on a top surface of the silicon carbide substrate. The epitaxial layer has a first conductivity type. The first electrode is disposed in the epitaxial layer in the first region and extends in a first direction. The separated conductive structure is disposed in the epitaxial layer in the first region. The separated conductive structure includes a first conductive feature and a second conductive feature separated from each other and located on opposite sidewalls of the first electrode. The source metal layer is disposed on the epitaxial layer in the first region. The source metal layer covers and is electrically connected to the first conductive feature, the second conductive feature and the first electrode.

Another embodiment of the disclosure provides a method for forming a semiconductor device. A method for forming a semiconductor device includes providing a silicon carbide substrate. The silicon carbide substrate has a first region and a first conductivity type. The method further includes growing an epitaxial layer on a top surface of the silicon carbide substrate. The epitaxial layer has the first conductivity type. The method further includes forming a first trench in the epitaxial layer in the first region along a first direction. The method further includes forming a first electrode in the first trench. The first electrode extends in the first direction. The method further includes forming a separated conductive structure on opposite sidewalls of the first electrode. The separated conductive structure includes a first conductive feature and a second conductive feature that are separated from each other. The method further includes entirely forming an interlayer dielectric layer. The method further includes removing the interlayer dielectric layer on a top surface of the epitaxial layer in the first region, so that the first electrode and at least one of the first conductive feature and the second conductive feature are exposed from the remaining interlayer dielectric layer. The method further includes forming a source metal layer on the epitaxial layer in the first region. The source metal layer covers and is electrically connected to the first electrode, the first conductive feature and the second conductive feature.

### BRIEF DESCRIPTION OF THE DRAWINGS

The present invention can be more fully understood by reading the subsequent detailed description and examples with references made to the accompanying drawings, wherein:

FIGS. 1A and 1B are schematic cross-sectional views of semiconductor devices in accordance with some embodiments of the disclosure;

FIGS. 2, 3, 4, 5, 6, 7, 8, 9, 10, 11, 12, 13, 14, 15, 16, 17, 18, 19, 20, 21, and 22 are schematic cross-sectional views of intermediate stages of forming the semiconductor device of FIGS. 1A and 1B in accordance with some embodiments of the disclosure; and

FIG. 23 is a schematic top view of an intermediate stage of forming the semiconductor device of FIGS. 1A and 1B in accordance with some embodiments of the disclosure, showing the arrangement of the source region and the pick-up doped region located on the well region.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a shielded gate trench metal-oxide-semiconductor field-effect transistor (SGT MOSFET) unit array, a Schottky diode can be arranged as a bypass diode to divert the reverse current flowing through the shielded gate trench metal-oxide-semiconductor field-effect transistor (SGT MOSFET) to the Schottky diode to improve the switching characteristics of the semiconductor device. However, the forward voltage drop (VF) of the conventional Schottky diode still needs to be further reduced. Therefore, a novel semiconductor device such as a shielded gate trench metal-oxide-semiconductor field-effect transistor (SGT MOSFET) and a method for forming the same are desired to solve or improve the abovementioned problems.

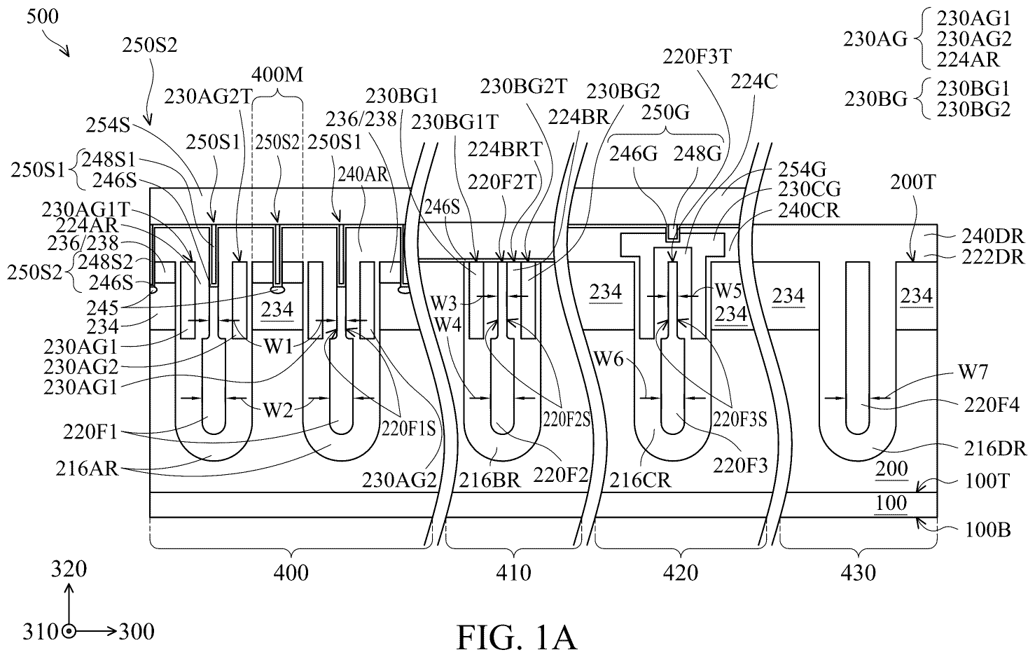

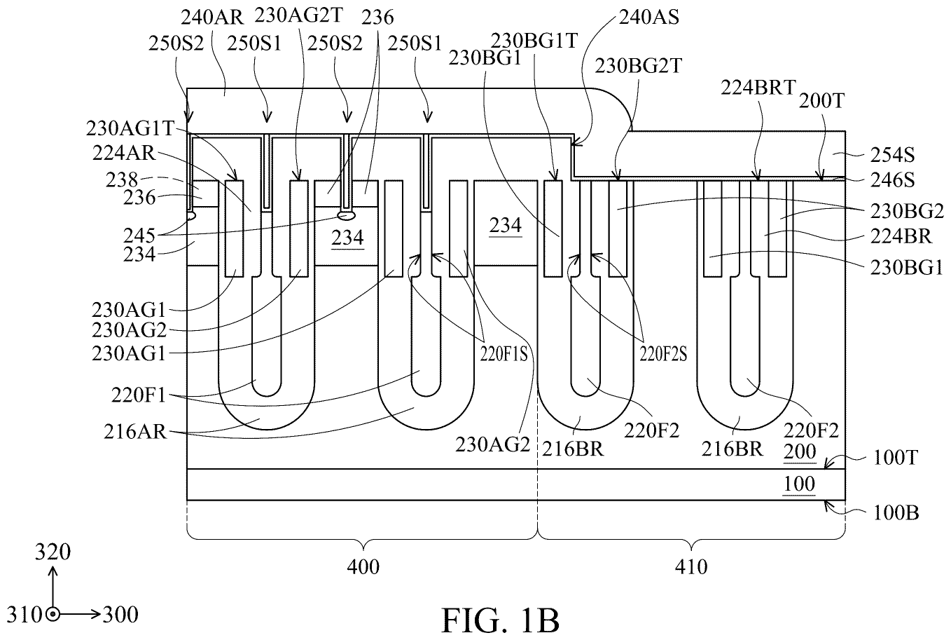

FIGS. 1A and 1B are schematic cross-sectional views of a semiconductor device 500 in accordance with some embodiments of the disclosure. More specifically, FIG. 1A is a schematic cross-sectional view of different regions of the semiconductor device 500 in accordance with some embodiments of the disclosure. FIG. 1B is a schematic cross-sectional view of a cell region and a trench metal-oxide-semiconductor (MOS) barrier Schottky (TMBS) region of the semiconductor device 500 (FIG. 1A) in accordance with some embodiments of the disclosure, which shows the component arrangements at the boundary between the cell region and the trench MOS barrier Schottky (TMBS) region. In some embodiments, the semiconductor device 500 includes a power metal-oxide-semiconductor field-effect transistor (power MOSFET) and a Schottky diode, for example, a shielded gate trench metal-oxide-semiconductor field-effect transistor (SGT MOSFET) integrated with a trench MOS barrier Schottky diode region and having a split-gate structure. As shown in FIGS. 1A and 1B, the semiconductor device 500 includes a silicon carbide (SiC) substrate 100, an epitaxial layer 200, an electrode 220F1, an electrode 220F2, a split gate structure 230AG, a separated conductive structure 230BG, and a source metal layer 254S. In FIGS. 1A and 1B and following figures, directions 300 and 310 are directions that are substantially parallel to the top surface 100T of the silicon carbide substrate 100 and may also serve as lateral directions. The direction 320 is the direction that is substantially perpendicular to the top surface 100T of the silicon carbide substrate 100 and may also serve as the longitudinal (vertical) direction (or may serve as the channel length direction). Moreover, the direction 300 is perpendicular to the directions 310 and 320, the direction 310 is perpendicular to the directions 300 and 320, and the direction 320 is perpendicular to the directions 300 and 310.

As shown in FIGS. 1A and 1B, the silicon carbide substrate 100 has a top surface 100T and a bottom surface 100B. Furthermore, the silicon carbide substrate 100 has a first region 400, a second region 410, a third region 420 and a fourth region 430. In some embodiments, the first region 400 may be a cell region providing a power metal-oxide-semiconductor field-effect transistor array formed within. The second region 410 may be a trench MOS barrier Schottky diode region (TMBS region), which may be connected in parallel with the shielded gate trench metal-oxide-semiconductor field-effect transistor unit in the cell region to reduce the on-resistance of the semiconductor device, thereby reducing power losses. The third region 420 may be a gate pickup region providing a gate contact formed thereon. In addition, the fourth region 430 may be a termination region, which is used to surround the cell region and serve as a buffer region for a doped region in the cell region to avoid a sudden drop in the device breakdown voltage at the boundary of the cell region. In the following embodiments, two shielded gate trench metal-oxide-semiconductor field-effect transistor units are used as an example for the structural description in the cell region (the first region 400). Furthermore, one trench electrode (for example, a source electrode) is used as an example for the structural description in the trench MOS barrier Schottky diode region (the second region 410), the gate pickup region (third region 420) and the terminal region (the fourth region 430). However, any number of shielded gate trench metal-oxide-semiconductor field-effect transistor units and trench electrodes may be disposed in the cell region, the gate pickup region, and the terminal region, and are not limited to the disclosed embodiments.

In some embodiments, the conductivity type of the silicon carbide substrate 100 may be P-type or N-type according to design requirements of the products. In this embodiment, the silicon carbide substrate 100 may be doped with dopants to have a first conductivity type, such as N-type. In the applications of vertical trench-gate metal-oxide-semiconductor field-effect transistor (vertical trench-gate MOSFET), the silicon carbide substrate 100 having the first conductivity type may be used as a drain region of the resulting semiconductor device 500.

The epitaxial layer 200 is disposed on the top surface 100T of the silicon carbide substrate 100. In some embodiments, the epitaxial layer 200 may be doped with dopants to have the first conductivity type. For example, when the silicon carbide substrate 100 is an N-type silicon carbide substrate 100, the epitaxial layer 200 is an N-type epitaxial layer 200. Moreover, the doping concentration of the epitaxial layer 200 (for example, about 10¹⁵-10¹⁶ atoms/cm³) is lighter than the doping concentration of the silicon carbide substrate 100 (for example, about 10¹⁹-10²¹ atoms/cm³). For example, when the silicon carbide substrate 100 is an N-type heavily doped (N+) silicon carbide substrate 100, the epitaxial layer 200 is an N-type lightly doped (N—) epitaxial layer 200. In the applications of vertical trench-gate metal-oxide-semiconductor field-effect transistor (the vertical trench-gate MOSFET), the epitaxial layer 200 having the first conductivity type may serve as a drift region of the resulting semiconductor device 500. In some embodiments, the epitaxial layer 200 includes silicon carbide.

The well region 234 of the semiconductor device 500 is located in the epitaxial layer 200 in the first region 400, the third region 420, and the fourth region 430, and is close to the top surface 200T of the epitaxial layer 200. In other words, there is no well region 234 located in the epitaxial layer 200 of the trench MOS barrier Schottky diode region (the second region 410). In some embodiments, the well region 234 may be doped with dopants to have a second conductivity type that is opposite to the first conductivity type. For example, when the silicon carbide substrate 100 is an N-type silicon carbide substrate 100, the well region 234 is a P-type well region 234. Furthermore, the dopant having the second conductivity type may include aluminum (Al), boron (B) or other suitable dopants. In some embodiments, the doping concentration of the well region 234 (e.g., about 10¹⁷-10¹⁸ atoms/cm³) is greater than the doping concentration of the epitaxial layer 200. In some embodiments, an ion implantation process may be used to form the well region 234. In the applications of vertical trench-gate metal-oxide-semiconductor field-effect transistors, the well region 234 having the second conductivity type may serve as a channel region of the resulting semiconductor device 500.

The source regions 236 of the semiconductor device 500 is located on the well region 234 in the first region 400 and is close to the top surface 200T of the epitaxial layer 200. Furthermore, the source region 236 may not be included in the second region 410, the third region 420, and the fourth region 430. As shown in FIGS. 1A and 1B, the source region 236 is surrounded by the well region 234. In some embodiments, the source region 236 may be doped with dopants to have the first conductivity type. For example, when the silicon carbide substrate 100 is an N-type silicon carbide substrate 100, the source region 236 is an N-type source region 236. Furthermore, the doping concentration of the source region 236 is greater than the doping concentration of the epitaxial layer 200. For example, when the epitaxial layer 200 is an N-type lightly doped (N—) epitaxial layer 200, the source region 236 is an N-type heavily doped (N+) source region 236.

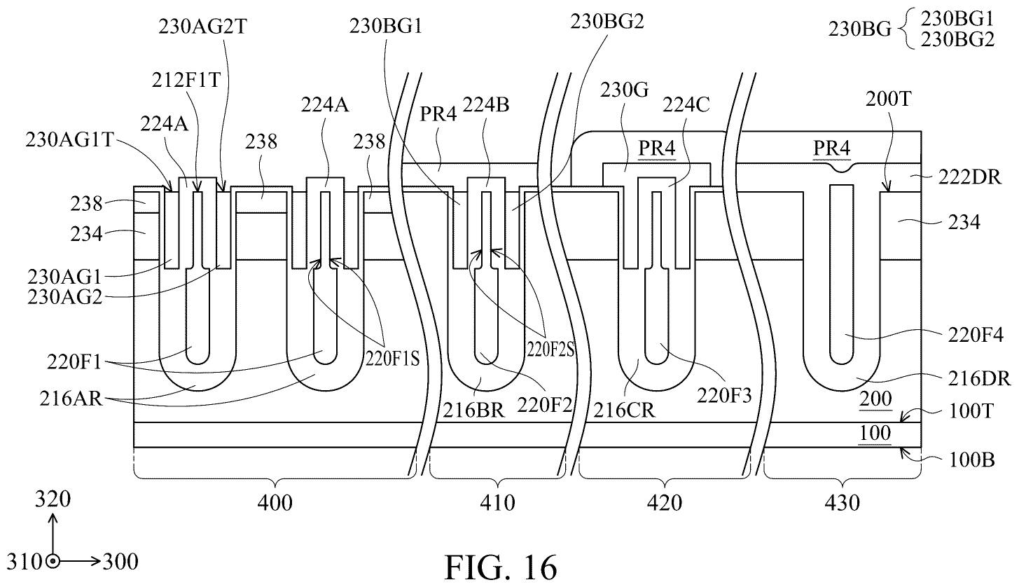

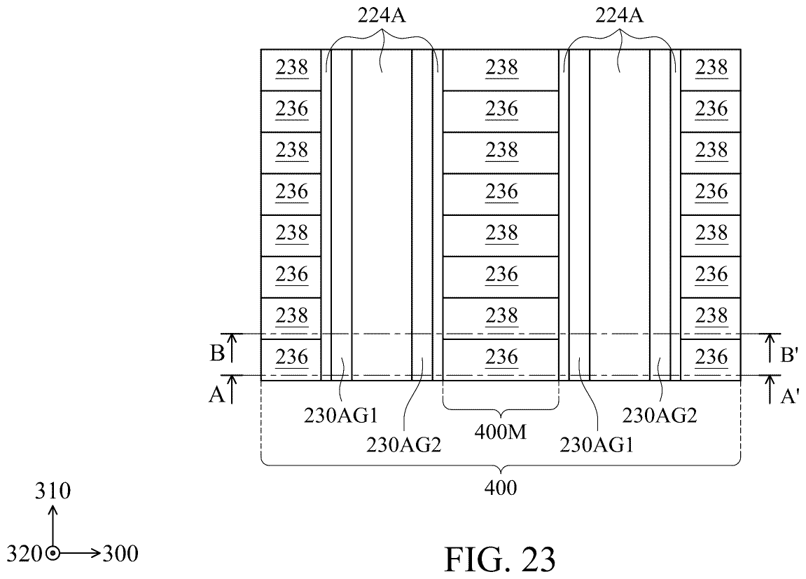

The semiconductor device 500 further includes pick-up doped regions 238 (FIGS. 16 and 23). The pick-up doped region 238 is located on the well region 234 in the first region 400 and is close to the top surface 200T of the epitaxial layer 200. Furthermore, the pick-up doped region 238 may not be included in the second region 410, the third region 420 and the fourth region 430. As shown in FIG. 16, the pick-up doped region 238 is surrounded by the well region 234. The source region 236 and the pick-up doped region 238 are adjacent to each other in the direction 310. Moreover, in some embodiments, the source regions 236 and the pick-up doped regions 238 are alternately arranged in the direction 310. The source region 236 and the pick-up doped region 238 may have opposite conductivity types. For example, when the source region 236 has the first conductivity type, the pick-up doped region 238 has the second conductivity type. The pick-up doped region 238 and the well region 234 may have the same conductivity type. For example, the pick-up doped region 238 may serve as the P-type pick-up doped region 238. Furthermore, the doping concentration of the pick-up doped region 238 is greater than the doping concentration of the well region 234. For example, when the well region 234 is a P-type well region 234, the pick-up doped region 238 is a P-type heavily doped (P+) pick-up doped region 238 to serve as the pick-up doped region of the well region 234.

The semiconductor device 500 further includes shielding dielectric layers 216AR, 216BR, 216CR, and 216DR and electrodes 220F1, 220F2, 220F3, and 220F4. As shown in FIGS. 1A and 1B, the shielding dielectric layer 216AR and the electrode 220F1 are disposed in the epitaxial layer 200 in the first region 400. The shielding dielectric layer 216AR is located below the top surface 200T of the epitaxial layer 200. The electrode 220F1 is located on the shielding dielectric layer 216AR. In addition, the shielding dielectric layer 216AR may cover the bottom surface and the opposite sidewalls of the electrode 220F1. As shown in FIGS. 1A and 1B, the electrode 220F1 may extend in the direction 320 toward the top surface 200T of the epitaxial layer 200 and the silicon carbide substrate 100. In some embodiments, in the direction 300, a width W1 of an upper portion of the electrode 220F1 (including the top portion 220F1-1) is less than a width W2 of a lower portion of the electrode 220F1.

As shown in FIG. 1A, the shielding dielectric layer 216BR and the electrode 220F2 are disposed in the epitaxial layer 200 in the second region 410. The second electrode 220F2 extends from a position close to the top surface 200T of the epitaxial layer 200 toward to the silicon carbide substrate 100 along the direction 320. The electrode 220F2 is located on the shielding dielectric layer 216BR. In addition, the shielding dielectric layer 216BR covers the bottom surface and opposite sidewalls of the electrode 220F2. In some embodiments, in the direction 300, a width W3 of an upper portion of the electrode 220F2 is less than a width W4 of a lower portion of the electrode 220F2. In some embodiments, the width W1 may be equal to the width W3, In addition, the width W2 may be equal to the width W4.

As shown in FIG. 1A, the shielding dielectric layer 216CR and the electrode 220F3 are disposed in the epitaxial layer 200 in the third region 420. The electrode 220F3 extends from a position close to the top surface 200T of the epitaxial layer 200 toward the silicon carbide substrate 100 along the direction 320. The electrode 220F3 is located on the shielding dielectric layer 216CR. In addition, the shielding dielectric layer 216CR covers the bottom surface and opposite sidewalls of the electrode 220F3. In some embodiments, in the direction 300, a width W5 of an upper portion of the electrode 220F3 is less than a width W6 of a lower portion of the electrode 220F3. In some embodiments, the width W5 may be equal to the widths W1, W3. In addition, the width W6 may be equal to the widths W2, W4.

As shown in FIG. 1A, the shielding dielectric layer 216DR and the electrode 220F4 are disposed in the epitaxial layer 200 in the fourth region 430. The fourth electrode 220F4 extends from a position close to the top surface 200T of the epitaxial layer 200 toward the silicon carbide substrate 100 along the direction 320. The electrode 220F4 is located on the shielding dielectric layer 216DR. In addition, the shielding dielectric layer 216DR covers the bottom surface and opposite sidewalls of the electrode 220F4. In some embodiments, in the direction 300, the electrode 220F4 has a uniform width W7. In some embodiments, the width W7 may be equal to the widths W1, W3, W5.

In some embodiments, the shielding dielectric layers 216AR, 216BR, 216CR, 216DR may include the same material. For example, the shielding dielectric layers 216AR, 216BR, 216CR, 216DR may include silicon oxide, other suitable semiconductor oxide materials, or a combination thereof. In some embodiments, the shielding dielectric layers 216AR, 216BR, 216CR, 216DR may be formed using a conformably deposition process, an oxidation process, or another suitable process. In some embodiments, the oxidation process may be thermal oxidation or another suitable process. In some embodiments, the deposition process may be a physical vapor deposition (PVD) process, a chemical vapor deposition (CVD) process, a plasma-enhanced chemical vapor deposition (PECVD) process, another suitable process, or a combination thereof.

In some embodiments, the electrodes 220F1, 220F2, 220F3, 220F4 may optionally include a dopant of the second conductivity type. For example, when the silicon carbide substrate 100 is an N-type silicon carbide substrate 100, the electrodes 220F1, 220F2, 220F3, 220F4 are respectively a P-type electrode 220F1, a P-type electrode 220F2, a P-type electrode 220F3, and a P-type electrode 220F4. Furthermore, the dopant having the second conductivity type may include aluminum (Al), boron (B), boron difluoride (BF2) or other suitable dopants. In some embodiments, the electrodes 220F1, 220F2, 220F3, 220F4 are electrically connected to the source contacts 250S1, 250S2.

In some embodiments, the electrode 220F1 in the first region 400 may reduce the gate-to-drain capacitance (C_{gd}) to improve the switching characteristics of the semiconductor device 500. In addition, the electrode 220F1 has a function of a field plate, such that the distribution of the electric field of the gate dielectric layer close to the bottom of the gate electrode 230AG (such as a gate dielectric layer 224A shown in FIG. 1, which will be described below) is relatively uniform and the breakdown voltage is increased. Therefore, the reliability of the gate dielectric layer is improved. In some embodiments, the electrode 220F2 in the second region 410 also has a function of a field plate, such that the distribution of the electric field of the epitaxial layer (the drift region) 200 is relatively uniform. Furthermore, through the arrangement of electrodes 220F1 and 220F2, the doping concentration of the epitaxial layer (the drift region) 200 can be further increased in order to reduce the on-resistance (Rₒₙₛₚ) of the shielded gate trench metal-oxide-semiconductor field-effect transistor unit in the first region 400, and reduce the forward voltage drop (VF) of the trench MOS barrier Schottky diode in the second region 410.

In the embodiment shown in FIGS. 1A and 1B, two split gate structures 230AG are disposed in the epitaxial layer 200 in the first region 400 and are located above the a lower portion of the electrode 220F1. The two split gate structures 230AG are separated from each other along the direction 300 by the epitaxial layer 200. Furthermore, the region of the epitaxial layer 200 between the two split gate structures 230AG may serve as a mesa region 400M of the semiconductor device 500. As shown in FIGS. 1A and 1B, the split gate structure 230AG extends in the direction 320. In some embodiments, the split gate structure 230AG includes the gate dielectric layer 224AR and the gate electrodes 230AG1, 230AG2 separated from each other along the direction 300. In some embodiments, the split gate structure 230AG may further reduce the whole gate-to-drain capacitance (C_{gd}) and feedback capacitance (Cᵣₛₛ=C_{gd}) to improve the whole power conversion efficiency of the semiconductor device 500

As shown in FIGS. 1A and 1B, the gate dielectric layer 224AR is disposed in the epitaxial layer 200 in the first region 400. The gate dielectric layer 224AR may extend from a position close to the top surface 200T of the epitaxial layer 200 into the epitaxial layer 200 along the direction 320. The top portion of the electrode 220F1 is exposed from gate dielectric layer 224AR of the split gate structure 230AG.

In some embodiments, the gate dielectric layer 224AR may include silicon oxide, silicon nitride, silicon oxynitride, tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glass (OSG), low dielectric constant dielectric materials, and/or other suitable dielectric materials, or a combination thereof. In this embodiment, the gate dielectric layer 224AR may include silicon oxide. In some embodiments, the shielding dielectric layers 216AR, 216BR, 216CR and the gate dielectric layer 224AR may be made of the same or different materials according to actual requirements of products. In some embodiments, the gate dielectric layer 224AR may be formed by an oxidation process and a deposition process. In some embodiments, the oxidation process may include thermal oxidation or another suitable process. In some embodiments, the deposition process may include a spin-on coating process, a chemical vapor deposition (CVD) process, an atomic layer deposition (ALD) process, a low pressure vapor deposition (LPCVD) process, a high-density plasma chemical vapor deposition (HDPCVD) process, another suitable process, or a combination thereof.

The gate electrodes 230AG1 and 230AG2 are located on opposite sidewalls 220F1S of the electrode 220F1 and extend in the direction 320. The top surfaces 230AGIT and 230AG2T of the gate electrodes 230AG1 and 230AG2 may be aligned with the top surface 200T of the epitaxial layer 200 (the top surfaces 230AGIT, 230AG2T and 200T are coplanar). In addition, the gate dielectric layer 224AR may surround the gate electrodes 230AG1 and 230AG2. Moreover, the electrode 220F1 may extend from below the gate electrodes 230AG1 and 230AG2 to the top surfaces 230AGIT and 230AG2T of the gate electrodes 230AG1 and 230AG2 along the direction 320. Furthermore, the electrode 220F1 may be interposed between the gate electrodes 230AG1 and 230AG2 in the direction 300. The opposite sidewalls 220F1S of the electrode 220F1 close to the gate electrodes 230AG1, 230AG2 are separated from the gate electrodes 230AG1, 230AG2 by the gate dielectric layer 224AR.

In some embodiments, the gate electrodes 230AG1 and 230AG2 may be single-layer structures or multi-layer structures and formed of amorphous silicon, polycrystalline silicon, one or more kinds of metals, metal nitride, metal silicide, conductive metal oxide, or a combination thereof. In some embodiments, the metal may include, but are not limited to, tungsten (W), titanium (Ti), tantalum (Ta) or platinum (Pt). In some embodiments, the metal nitrides may include, but are not limited to, titanium nitride (TiN) or tantalum nitride (TaN). In some embodiments, the metal silicide may include, but is not limited to, tungsten silicide (WSiₓ). In some embodiments, the gate electrodes 230AG1, 230AG2 may optionally include a dopant of the second conductivity type. For example, when the silicon carbide substrate 100 is an N-type silicon carbide substrate 100, the gate electrodes 230AG1 and 230AG2 are P-type gate electrodes 230AG1 and 230AG2. Furthermore, the dopant having the second conductivity type may include aluminum (Al), boron (B), boron difluoride (BF2) or other suitable dopants. In some embodiments, the electrodes 220F1, 220F2, 220F3, 220F4 may include the same or different materials as the gate electrodes 230AG1, 230AG2.

As shown in FIGS. 1A and 1B, the separated conductive structure 230BG is disposed in the epitaxial layer 200 in the second region 410. In some embodiments, the split gate structure 230AG and the separated conductive structure 230BG may have similar structures. However, at least one difference between the separated conductive structure 230BG and the gate electrodes 230AG1 and 230AG2 is that the separated conductive structure 230BG is not surrounded by the well region 234. For example, the well region 234 may be adjacent to only one of the opposite sides of the separated conductive structure 230BG in the direction 300, or may not be adjacent to the opposite sides of the separated conductive structure 230BG in the direction 300. In some embodiments, the separated conductive structure 230BG includes conductive features 230BG1, 230BG2 that are separated from each other in the direction 300.

As shown in FIGS. 1A and 1B, the semiconductor device 500 further includes a dielectric layer 224BR. The dielectric layer 224BR is disposed in the epitaxial layer 200 in the second region 410. The dielectric layer 224BR may extend from a position close to the top surface 200T of the epitaxial layer 200 into epitaxial layer 200 along the direction 320. The top surface 220F2T of the electrode 220F2 is exposed from the top surface 224BRT of the dielectric layer 224BR. More specifically, the top surface 220F2T of the electrode 220F2 may be aligned with the top surface 200T of the epitaxial layer 200 (the top surfaces 220F2T and 200T are coplanar).

In some embodiments, the dielectric layer 224BR and the gate dielectric layer 224AR may include the same or similar materials and processes. In this embodiment, the dielectric layer 224BR may include silicon oxide. In some embodiments, the shielding dielectric layers 216AR, 216BR, 216CR, the gate dielectric layer 224AR and the dielectric layer 224BR may be made of the same or different materials according to actual requirements of products. In some embodiments, the dielectric layer 224BR and the gate dielectric layer 224AR may be formed simultaneously.

The conductive features 230BG1, 230BG2 are located on opposing sidewalls 220F2S of the electrode 220F2 and extend in the direction 320. Top surfaces 230BGIT and 230BG2T of the conductive features 230BG1 and 230BG2 may be aligned with the top surface 200T of the epitaxial layer 200 and the top surface 220F2T of the electrode 220F2 (the top surfaces 230BGIT, 230BG2T, 200T and 220F2T are coplanar). The dielectric layer 224BR may surround the conductive features 230BG1, 230BG2. Furthermore, the top surfaces 230BGIT and 230BG2T of the conductive features 230BG1 and 230BG2 are exposed from the top surface 224BRT of the dielectric layer 224BR. In additional, electrode 220F2 may extend from below the conductive features 230BG1, 230BG2 to the top surfaces 230BGIT, 230BG2T of the conductive features 230BG1, and 230BG2 in the direction 320. Also, the electrode 220F2 may be interposed between the conductive features 230BG1 and 230BG2 in the direction 300. The opposite sidewalls 220F2S of the electrode 220F2 close to the conductive features 230BG1, 230BG2 are separated from the conductive features 230BG1, 230BG2 by the dielectric layer 224BR.

In some embodiments, the conductive features 230BG1 and 230BG2 may be single-layer or multi-layer structures. The conductive features 230BG1 and 230BG2 may be formed of amorphous silicon, polycrystalline silicon, one or more kinds of metals, metal nitrides, metal silicides, conductive metal oxides, or a combination thereof. In some embodiments, the metals may include, but are not limited to, tungsten (W), titanium (Ti), tantalum (Ta), and platinum (Pt). In some embodiments, the metal nitrides may include, but are not limited to, titanium nitride (TiN) and tantalum nitride (TaN). In some embodiments, the metal silicides may include, but is not limited to, tungsten silicide (WSiₓ). In some embodiments, the conductive features 230BG1, 230BG2 may optionally include a dopant of the second conductivity type. For example, when the silicon carbide substrate 100 is an N-type silicon carbide substrate 100, the conductive features 230BG1 and 230BG2 are P-type conductive features 230BG1 and 230BG2. Furthermore, the dopant having the second conductivity type may include aluminum (Al), boron (B), boron difluoride (BF2) or other suitable dopants. In some embodiments, the electrodes 220F1, 220F2, 220F3, 220F4 may include the same or different materials as the conductive features 230BG1, 230BG2.

The semiconductor device 500 further includes a gate dielectric layer 224C and a gate electrode 230G disposed in the epitaxial layer 200 in the third region 420. The gate dielectric layer 224C may extend from a position close to the top surface 200T of the epitaxial layer 200 into the epitaxial layer 200 along the direction 320. Furthermore, the gate dielectric layer 224C may cover the top portion of the electrode 220F3. The gate electrode 230G is located on the gate dielectric layer 224C and connected to the split gate structure 230AG. In some embodiments, the gate electrode 230G may extend from opposite sidewalls 220F3S of the electrode 220F3 to cover the top surface 220F3T of the electrode 220F3 and the top surface 200T of epitaxial layer 200. The portion of the gate electrode 230G located on the opposite sidewall 220F3S of the electrode 220F3 may extend along the direction 320. Furthermore, a portion of the gate electrode 230G located above the top surface 220F3T of the electrode 220F3 and the top surface 200T of the epitaxial layer 200 may extend along the direction 300.

The semiconductor device 500 further includes interlayer dielectric layers 240AR, 240CR, and 240DR. The interlayer dielectric layers 240AR, 240CR, and 240DR are disposed on the epitaxial layer 200 in the first region 400, the third region 420, and the fourth region 430. The interlayer dielectric layer 240AR may cover the gate electrode 230AG1, the gate electrode 230AG2, the gate dielectric layer 224AR, the pick-up doped region 238 and the gate electrode 230G. The interlayer dielectric layer 240CR may cover the gate dielectric layer 224C and the gate electrode 230G. The interlayer dielectric layer 240DR may cover the electrode 220F4. In addition, the conductive feature 230BG1 and/or the conductive feature 230BG2 and the electrode 220F2 may be exposed from the interlayer dielectric layers 240AR, 240CR, and 240DR. As shown in FIGS. 1A and 1B, the top surface 200T of the epitaxial layer 200 in the second region 410 may not be completely covered by the interlayer dielectric layer. For example, the interlayer dielectric layer 240AR may extend from the top surface 200T of the epitaxial layer 200 in the first region 400 to cover the conductive feature 230BG1 of the separated conductive structure 230BG close to the first region 400. In addition, the electrode 220F2 and the conductive feature 230BG2 are exposed from the interlayer dielectric layer 240AR. As shown in FIG. 1B, a sidewalls 240AS of the interlayer dielectric layer 240AR is located on the dielectric layer 224BR close to the electrode 220F2. For example, the sidewalls 240AS of the interlayer dielectric layer 240AR may be located on the dielectric layer 224BR between the conductive feature 230BG1 and the electrode 220F2. Furthermore, the interlayer dielectric layers 240AR, 240CR, and 240DR do not cover other separated conductive structures 230BG. In some embodiments, the interlayer dielectric layers 240AR, 240CR, 240DR may include silicon oxide, silicon nitride, silicon oxynitride, phosphorus silicate glass (PSG), borophosphosilicate glass (BPSG), or a combination thereof. In some embodiments, the interlayer dielectric layers 240AR, 240CR, and 240DR may be formed using a conformably deposition process, an oxidation process, other suitable formation processes, and a subsequent patterning process. In some embodiments, the oxidation process may be thermal oxidation or other suitable processes. In some embodiments, the deposition process may include a physical vapor deposition (PVD) process, a chemical vapor deposition (CVD) process, a plasma-enhanced chemical vapor deposition (PECVD), another suitable process, or a combination thereof.

The source contacts 250S1 and 250S2 are disposed on the epitaxial layer 200 in the first region 400. The source contacts 250S1 and 250S2 may be formed passing through the interlayer dielectric layer 240AR in the first region 400. Furthermore, the source contact 250S1 may extend into the partial electrode 220F1 along the direction 320. The source contact 250S2 may be formed passing through the source region 236 (and the pick-up doped region 238), and extends into a portion of the well region 234 along the direction 320. The source contact 250S1 is electrically connected to the electrode 220F1. The source contact 250S2 is electrically connected to the source region 236 and the pick-up doped region 238. As shown in FIGS. 1A and 1B, there are two source contact 250S2 respectively disposed in the source regions 236 (and the pick-up doped regions 238) (for example, in the mesa region 400M) on both sides of the split gate structure 230AG. In addition, there is one source contact 250S1 disposed in the upper portion of the electrode 220F1 used to separate the gate electrodes 230AG1 and 230AG2. Therefore, the source contact 250S1 is sandwiched between the two source contacts 250S2. The source contacts 250S1 and 250S2 can be electrically connected to the conductive features 230BG1 and 230BG2 and the electrodes 220F2, 220F3 and 220F4 through other interconnections (not shown). Furthermore, the gate electrodes 230AG1 and 230AG2 may be separated from the source contacts 250S1 and 250S2 by the gate dielectric layer 224AR.

In some embodiments, the source contact 250S1 may include a contact barrier layer 246S and a contact conductive layer 248S1. The source contact 250S2 may include the contact barrier layer 246S and a contact conductive layer 248S2. In some embodiments, the source contacts 250S1, 250S2 are formed simultaneously. As shown in FIG. 1B, the contact barrier layer 246S may continuously cover the top surface 200T of the epitaxial layer 200 in the first region 400 and the second region 410, and extend into a portion of the epitaxial layer 200 in the first region 400. The contact barrier layer 246S may cover and is in physical contact with the top surface 220F2T of the electrode 220F2. In addition, the contact barrier layer 246S may cover and is in physical contact with at least one of the top surface 230BGIT of the conductive feature 230BG1 and the top surface 230BG2T of the conductive feature 230BG2. The contact barrier layer 246S may be used to prevent the subsequently formed contact conductive layers 248S1 and 248S2 from diffusing into the gate electrodes 230AG1 and 230AG2. The contact barrier layer 246S may be formed of a material including titanium (Ti), titanium nitride (TiN), tantalum (Ta), tantalum nitride (TaN), cobalt (Co), other suitable barrier materials, or a combination thereof. In some embodiments, the contact barrier layer 246S may be formed using a chemical vapor deposition (CVD) process, an atomic layer deposition (ALD) process, a physical vapor deposition (PVD) process, another suitable process, or a combination thereof.

In some embodiments, the contact conductive layers 248S1 and 248S2 of the source contacts 250S1 and 250S2 may be single-layer or multi-layer structures. The contact conductive layers 248S1 and 248S2 may be formed of a material including tungsten (W), aluminum (Al), copper (Cu), titanium (Ti), tantalum (Ta), titanium nitride (TiN), tantalum nitride (TaN), nickel silicide (NiSi), cobalt silicide (CoSi), other suitable metals, or a combination thereof. In some embodiments, the contact conductive layers 248S1 and 248S2 may be formed using a chemical vapor deposition (CVD) process, an atomic layer deposition (ALD) process, a physical vapor deposition (PVD) process, another suitable process, or a combination thereof.

The semiconductor device 500 further includes a gate contact 250G. The gate contact 250G is disposed on the epitaxial layer 200 in the third region 420. The gate contact 250G may be formed from above the interlayer dielectric layer 240CR, passing through the interlayer dielectric layer 240CR along the direction 320 and extending into a portion of the gate electrode 230G to electrically connect the gate electrode 230G. Similar to the source contacts 250S1, 250S2, the gate contact 250G may include a contact barrier layer 246G and a contact conductive layer 248G. In some embodiments, the contact barrier layers 246S and 246G include the same or similar materials and processes, and may be formed simultaneously. Furthermore, the contact barrier layer 246S and contact barrier layer 246G are spaced apart from each other. The contact conductive layers 248S1, 248S2, and 248G may include the same or similar materials and processes, and may be formed simultaneously.

As shown in FIGS. 1A and 1B, the semiconductor device 500 further includes a source metal layer 254S and a gate metal layer 254G that are separated from each other. The source metal layer 254S may extend from the epitaxial layer 200 in the first region 400 to cover the epitaxial layer 200 of the second region 410. In addition, the source metal layer 254S is electrically connected to the electrode 220F2, the source region 236 (and the pick-up doped region 238) and the well region 234 through the source contacts 250S1, 250S2. Furthermore, the source metal layer 254S is in electrical contact with the conductive features 230BG1 and 230BG2 through the contact barrier layer 246S. The gate metal layer 254G may cover the epitaxial layer 200 in the third region 420. In addition, the gate metal layer 254G is electrically connected to the gate electrode 230G through the gate contact 250G. The source metal layer 254S and the gate metal layer 254G may belong to the top metal layer of the resulting semiconductor device 500. The conductive feature 230BG1 and the conductive feature 230BG2 may be electrically connected to the electrode 220F1, the electrode 220F2, the source region 236 and the well region 234 by the source metal layer 254S. As shown in FIG. 1B, the source metal layer 254S located in the second region 410 and the contact barrier layer 246S below the source metal layer 254S may collectively form a Schottky junction with the epitaxial layer 200 between two adjacent pairs of separated conductive structures 230BG. In addition, the source metal layer 254S may also be electrically connected to the electrodes 220F3 and 220F4 through other interconnections (not shown). The gate metal layer 254G may be electrically connected to the gate electrode 230G through the gate contact 250G.

As shown in FIG. 1B, the source metal layer 254S and the contact barrier layer 246S thereunder located in the second region 410, and the epitaxial layer 200 between two adjacent pairs of separated conductive structures 230BG (the drift region) may collectively form a Schottky diode. The intrinsic parasitic diode at the interface between the well region 234 and the epitaxial layer 200 (the drift region) of different conductivity types is called a body diode. The Schottky diode in accordance with some embodiments of the disclosure and the body diode are connected in parallel. Since the energy barrier of the Schottky diode is lower than that of the base diode, that is, the on-resistance (Rₒₙₛₚ) of the Schottky diode is lower than that of the base diode. When a semiconductor device is in operation, carriers will flow through the Schottky diode instead of the body diode. Therefore, the arrangement of the Schottky diode in the semiconductor device in accordance with some embodiments of the disclosure may disable the base diode. Furthermore, the semiconductor device may achieve the benefits of lowering on-resistance and reducing power losses.

In some embodiments, the source metal layer 254S and the gate metal layer 254G may include copper, silver, gold, aluminum, tungsten, other suitable metal materials, or a combination thereof. In some embodiments, the source metal layer 254S, the gate metal layer 254G, the source contacts 250S1, 250S2, and the gate contact 250G may include the same material, or different materials. In some embodiments, the source metal layer 254S and the gate metal layer 254G are formed by a deposition process and a subsequent patterning process. In some embodiments, the deposition process may include a physical vapor deposition (PVD), a chemical vapor deposition (CVD), another suitable process, or a combination thereof.

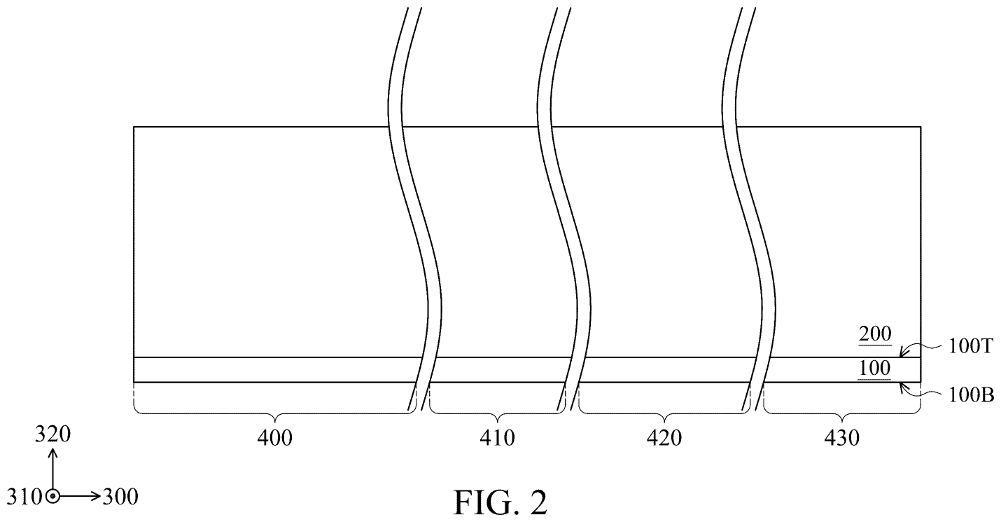

The method for forming the semiconductor device 500 in accordance with some embodiments of the disclosure will be described with reference to FIGS. 2 to 22. FIGS. 2 to 22 schematic cross-sectional views of intermediate stages of forming the semiconductor device 500 of FIGS. 1A and 1B in accordance with some embodiments of the disclosure, in which the reference numbers the same or similar to those in FIGS. 1A and 1B denote the same or similar elements.

As shown in FIG. 2, the silicon carbide substrate 100 having the first conductivity type, for example, an N-type heavily doped (N+) silicon carbide substrate 100, is provided.

Next, an epitaxial growth process is performed to grow the epitaxial layer 200 of the first conductivity type, such as an N-type lightly doped (N—) silicon carbide epitaxial layer 200, on the top surface 100T of the silicon carbide substrate 100. In some embodiments, the epitaxial process includes metal organic chemical vapor deposition (MOCVD), plasma-enhanced chemical vapor deposition (PECVD), molecular beam epitaxy (MBE), hydride vapor phase epitaxy (HVPE), liquid phase epitaxy (LPE), chloride vapor phase epitaxy (Cl-VPE), other suitable epitaxial growth processes or a combination thereof.

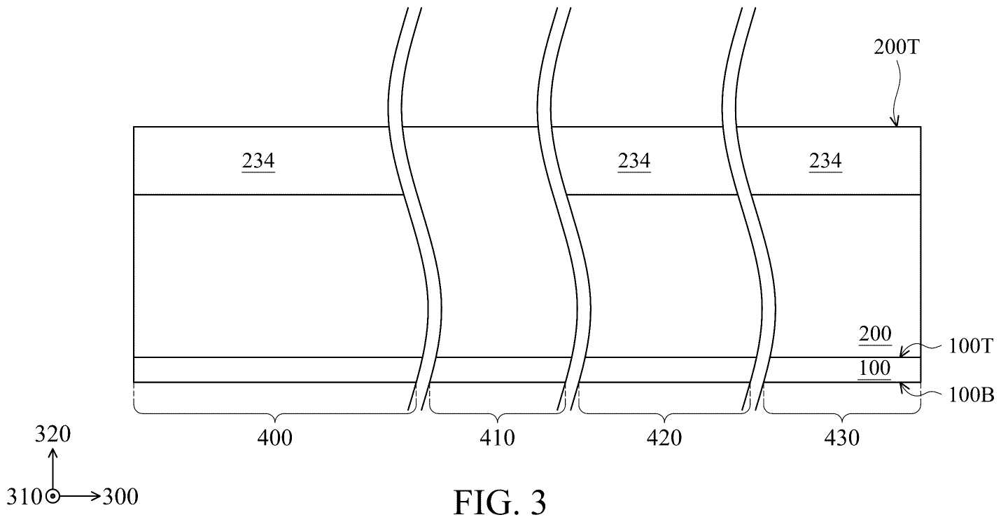

Then, as shown in FIG. 3, a photolithography process and a subsequent ion implantation process may be performed form the well region 234 having the second conductivity type, such as a P-type well region 234, in the epitaxial layer 200 in the first region 400, the third region 420 and the fourth region 430. The well region 234 may extend from the top surface 200T of the epitaxial layer 200 in the first region 400, the third region 420 and the fourth region 430 into a portion of the epitaxial layer 200. There is no well region 234 located in the epitaxial layer 200 in the second region 410.

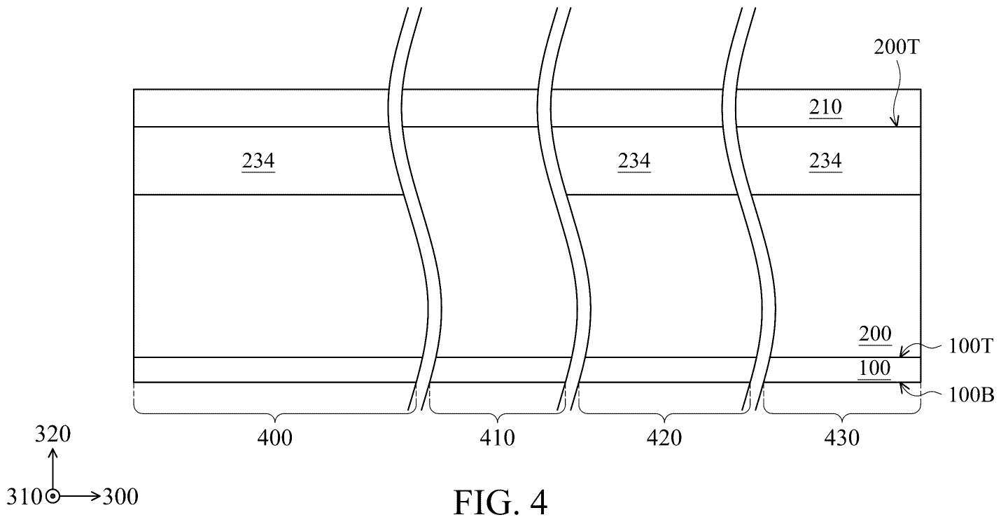

Next, as shown in FIG. 4, a deposition process may be performed to form a mask layer 210 on the epitaxial layer 200. In some embodiments, the mask layer 210 may be a single-layer structure or a multi-layer structure. In some embodiments, the mask layer 210 may include an insulating material such as silicon oxide.

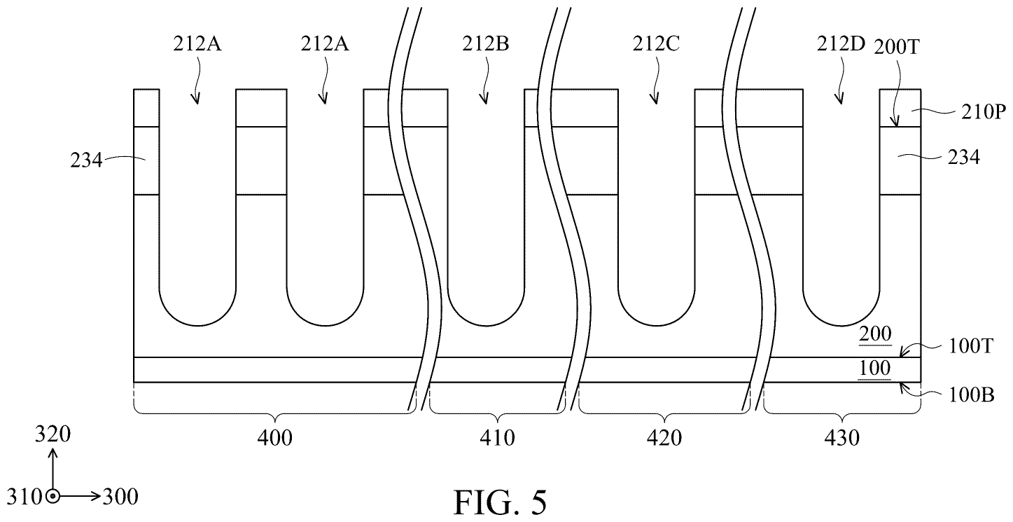

Next, as shown in FIG. 5, a photolithography process and a subsequent patterning process are performed to remove a portion of the mask layer 210, thereby forming a mask pattern 210P on the top surface 200T of the epitaxial layer 200 to define the formation locations of trenches. Next, an etching process is performed on the epitaxial layer 200 using the mask pattern 210P as an etching mask. The etching process removes the epitaxial layer 200 not covered by the mask pattern 210P to form trenches 212A, 212B, 212C, and 214D in the epitaxial layer 200 in the first region 400, the second region 410, the third region 420, and the fourth region 430 respectively along the direction 320. In the embodiment shown in FIG. 5, the etching process may form two trenches 212A in the epitaxial layer 200 in the first region 400, form one trench 212B in the epitaxial layer 200 in the second region 410, form one trench 212C in the epitaxial layer 200 in the third region 420 and form one trench 212D in the epitaxial layer 200 in the fourth region 430. The two adjacent trenches 212A are spaced apart from each other along the direction 300 and define the mesa region 400M of the epitaxial layer 200. In some embodiments, the etching process includes dry etching. Dry etching may include plasma etching, plasma-free gas etching, sputter etching, ion milling, reactive ion etching (RIE), neutral beam etch (NBE), inductive coupled plasma etch (inductive coupled plasma etch) or another suitable process.

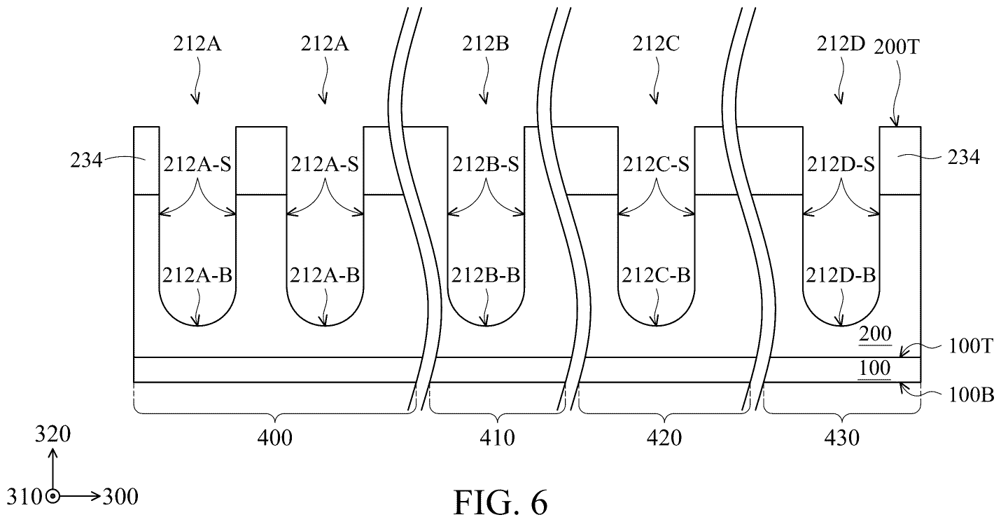

Next, as shown in FIG. 6, a selective etching process may be performed to remove the mask pattern 210P. Next, an oxidation process and a subsequent etching process may be performed to form a sacrificial (SAC) oxide layer (not shown) on sidewalls 212A-S, 212B-S, 212C-S, 212D-S and bottom surfaces 212A-B, 212B-B, 212C-B, 212D-B of the trenches 212A, 212B, 212C, and 212D. Another etching process is then performed to remove the sacrificial oxide layer, so that the sidewalls 212A-S, 212B-S, 212C-S, 212D-S and the bottom surfaces 212A-B, 212B-B, 212C-B, 212D-B of the trenches 212A, 212B, 212C, and 212D are exposed again. The oxidation process and etching process shown in FIG. 6 may remove the surface damage caused by the etching process (FIG. 5) that forms trenches 212A, 212B, 212C, and 212D.

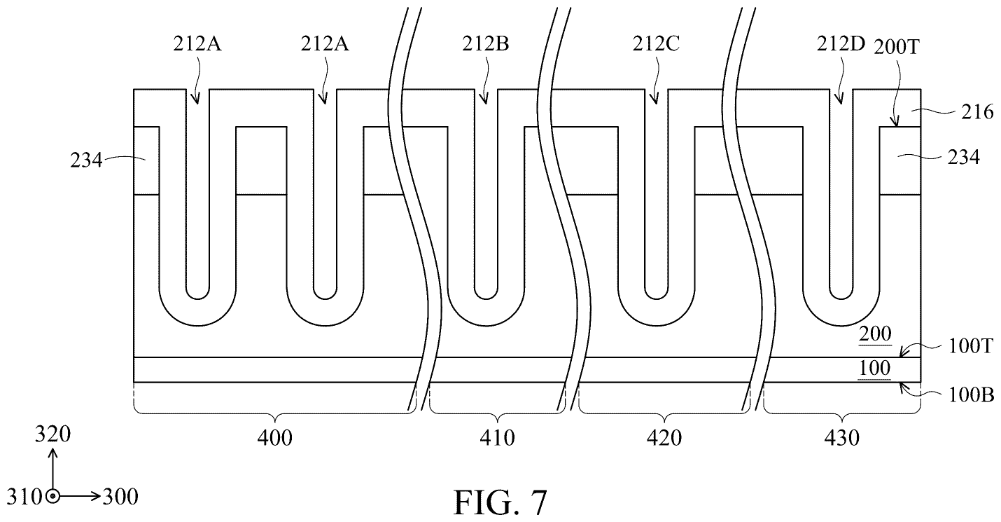

Next, as shown in FIG. 7, an oxidation process and a subsequent deposition process may be performed to entirely form a shielding dielectric layer 216. The shielding dielectric layer 216 may cover the top surface 200T of the epitaxial layer 200 and extend into the trenches 212A, 212B, 212C, and 212D. In addition, the shielding dielectric layer 216 may conformally cover the sidewalls 212A-S, 212B-S, 212C-S, 212D-S and the bottom surfaces 212A-B, 212B-B, 212C-B, 212D-B of the trenches 212A, 212B, 212C, and 212D (FIG. 6).

In some embodiments, the dielectric layer 216 may be optionally subjected to a thermal process to increase the density of the shielding dielectric layer 216 and improve the interface properties between the shielding dielectric layer 216 and the epitaxial layer 200. In some embodiments, the thermal process may be a rapid thermal annealing (RTA) process.

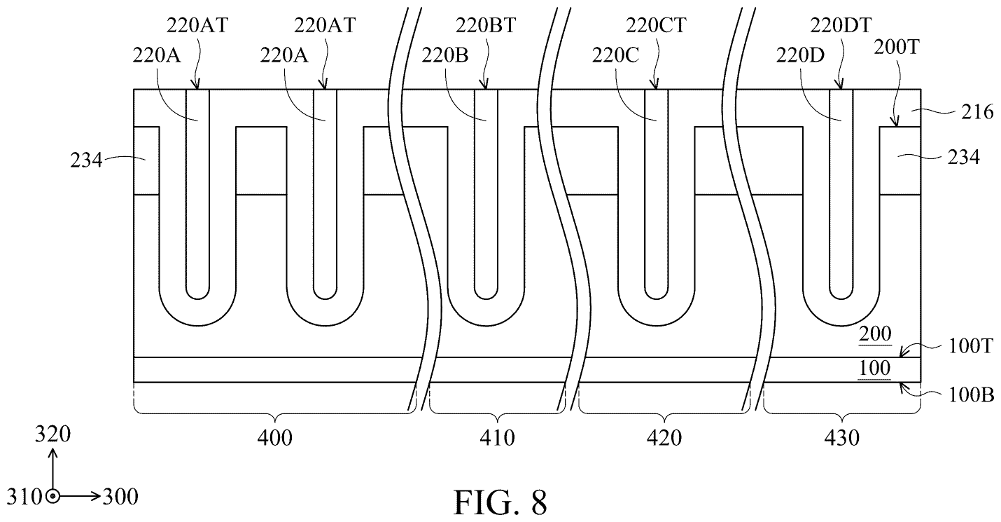

Next, as shown in FIG. 8, a deposition process and a subsequent planarization process may be performed to form conductive materials 220A, 220B, 220C, and 220D in the trenches 212A, 212B, 212C, and 212D (FIG. 7) respectively. In some embodiments, the conductive materials 220A, 220B, 220C, and 220D are formed simultaneously. The top surface 220AT of the conductive material 220A, the top surface 220BT of the conductive material 220B, the top surface 220CT of the conductive material 220C, and the top surface 220DT of the conductive material 220D are all higher than the top surface 200T of the epitaxial layer 200 and are aligned with each other. For example, the top surface 220AT of the conductive material 220A, the top surface 220BT of the conductive material 220B, the top surface 220CT of the conductive material 220C, and the top surface 220DT of the conductive material 220 are all aligned with the top surface 216T of the shielding dielectric layer 216. Furthermore, the conductive materials 220A, 220B, 220C, and 220D may include the same material. In some embodiments, the conductive materials 220A, 220B, 220C, and 220D may be formed of amorphous silicon, polycrystalline silicon, one or more kinds of metals, metal nitrides, metal silicides, conductive metal oxides, or a combination thereof. In some embodiments, the metals may include, but are not limited to, tungsten (W), titanium (Ti), tantalum (Ta), and platinum (Pt). In some embodiments, the metal nitrides may include, but are not limited to, titanium nitride (TiN) and tantalum nitride (TaN). In some embodiments, the metal silicides may include, but is not limited to, tungsten silicide (WSiₓ). In some embodiments, the deposition process may include metal organic chemical vapor deposition (MOCVD), sputtering, resistance heating evaporation, electron beam evaporation, or other suitable deposition processes. In some embodiments, the planarization process includes a chemical mechanical polishing (CMP) process.

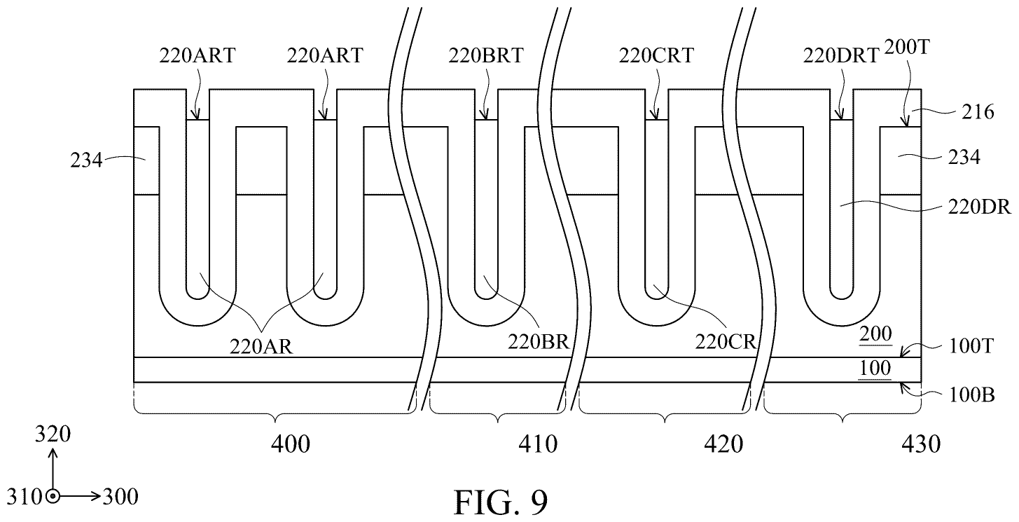

Next, as shown in FIG. 9, an etch-back process may be performed to remove a portion of the conductive materials 220A, 220B, 220C, and 220D from the top surfaces 220AT, 220BT, 220CT, and 220DT of the conductive materials 220A, 220B, 220C, and 220D. After performing the etching back process, the remaining conductive materials 220A, 220B, 220C, and 220D are denoted as conductive materials 220AR, 220BR, 220CR, and 220DR. Top surfaces 220ART, 220BRT, 220CRT, and 220DRT of the conductive materials 220AR, 220BR, 220CR, and 220DR may be located above the top surface 200T of the epitaxial layer 200. For example, the top surfaces 220ART, 220BRT, 220CRT, and 220DRT of the conductive materials 220AR, 220BR, 220CR, and 220DR may be higher than the top surface 200T of the epitaxial layer 200 and lower than the top surface 216T of the shielding dielectric layer 216. In some embodiments, the etch-back process may be a selective etching process, such as dry etching.

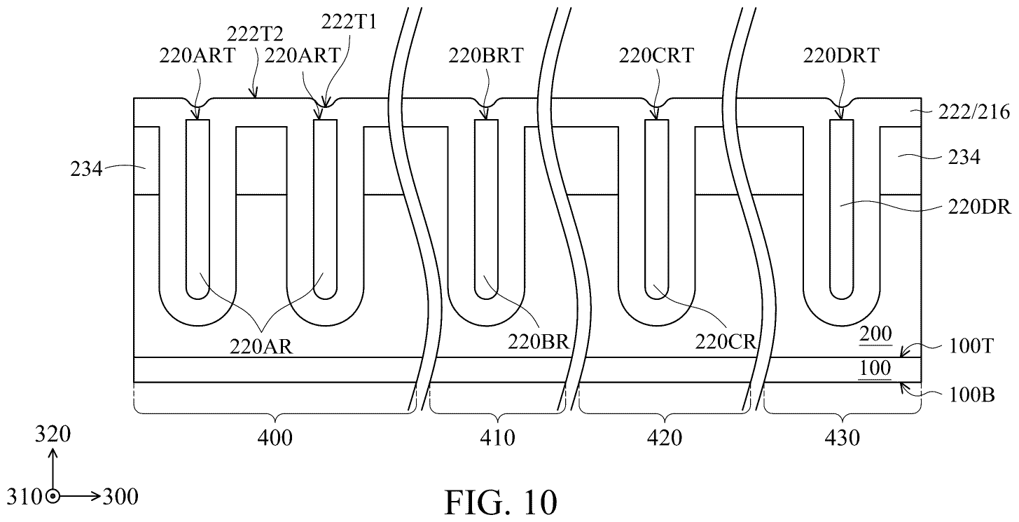

Next, as shown in FIG. 10, a deposition process may be performed to entirely form an oxide layer 222. The oxide layer 222 may cover the shielding dielectric layer 216 and the conductive materials 220AR, 220BR, 220CR, and 220DR. When the oxide layer 222 and the shielding dielectric layer 216 both include silicon oxide, there is no obvious interface between the oxide layer 222 and the shielding dielectric layer 216. In some embodiments, the oxide layer 222 includes tetraethoxysilane (TEOS) oxide formed using low pressure chemical vapor deposition (LPCVD). Since the top surfaces 220ART, 220BRT, 220CRT, and 220DRT of the conductive materials 220AR, 220BR, 220CR, and 220DR are lower than the top surface 216T of the shielding dielectric layer 216, an upper surface 222T1 of a portion of the oxide layer 222 directly above the conductive materials 220AR, 220BR, 220CR, and 220DR will be lower than an upper surface 222T2 of another portion of the oxide layer 222 directly above the shielding dielectric layer 216.

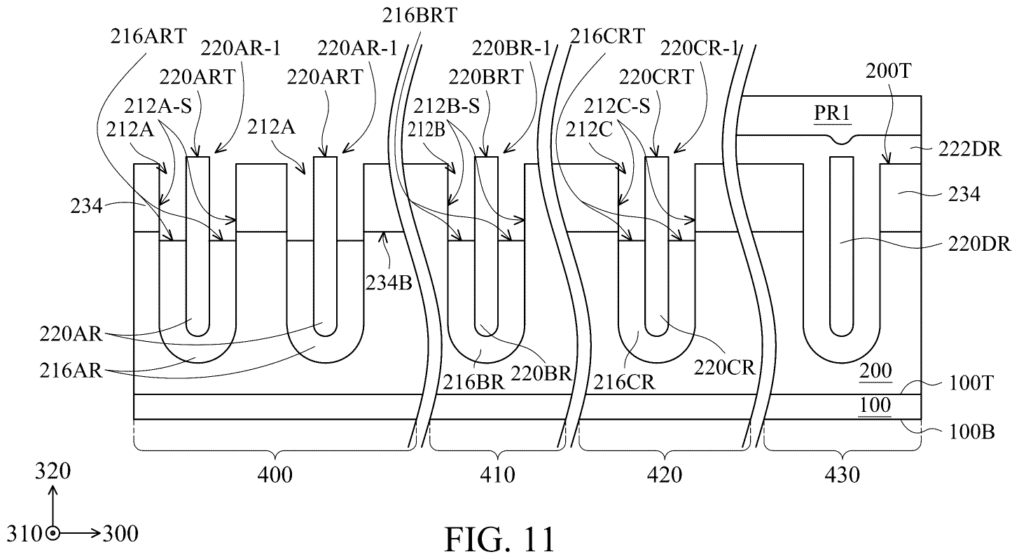

Next, as shown in FIG. 11, a photolithography process may be performed to form a mask pattern PR1 such as a photoresist pattern above the epitaxial layer 200 in the fourth region 430. The mask pattern PR1 may cover the conductive material 220DR and a portion of the shielding dielectric layer 216 and oxide layer 222 in the fourth region 430. In addition, a portion of the oxide layer 222 in the first region 400, the second region 410 and the third region 420 (FIG. 10) is exposed from the mask pattern PR1. Next, a selective etching process may be performed to remove the oxide layer 222 and a portion of the shielding dielectric layer 216 from the top surface 200T of the epitaxial layer 200 and the upper portions of the trenches 212A, 212B and 212C close to the top surface 200T of the epitaxial layer 200 (FIG. 10) until the upper portions 220AR-1, 220BR-1 and 220CR-1 of the conductive materials 220AR, 220BR and 220CR are exposed. After performing the selective etching process, the remaining portions of the shielding dielectric layer 216 in the trenches 212A, 212B and 212C in the first region 400, the second region 410 and the third region 420 are denoted as the shielding dielectric layers 216AR, 216BR and 216CR. The shielding dielectric layer 216 and the oxide layer 222 remaining in the fourth region 430 are denoted as the shielding dielectric layer 216DR and the oxide layer 222DR. The shielding dielectric layers 216AR, 216BR and 216CR may surround the lower portions of the conductive materials 220AR, 220BR and 220CR, and expose the sidewalls 212A-S, 212B-S and 212C-S of the upper portions of the trenches 212A, 212B and 212C. The top surfaces 216ART, 216BRT and 216CRT of the shielding dielectric layers 216AR, 216BR and 216CR may be located below the bottom surface 234B of the well region 234. The shielding dielectric layer 216DR and the oxide layer 222DR may surround the conductive material 220DR. In some embodiments, the selective etching process includes wet etching. After forming the shielding dielectric layers 216AR, 216BR, 216CR and 216DR, the mask pattern PR1 is removed.

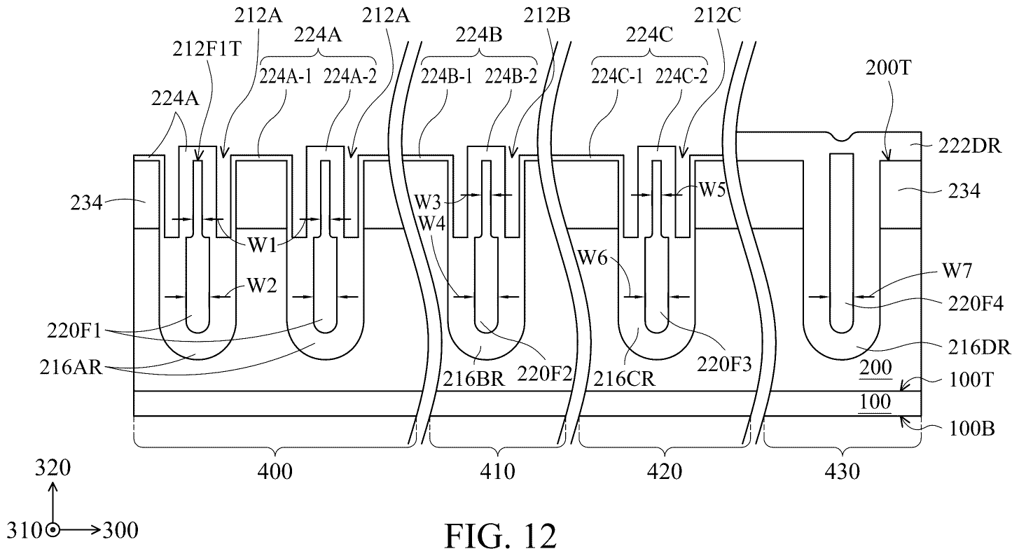

Next, as shown in FIG. 12, an oxidation process may be performed to form gate dielectric layers 224A, 224C in the trenches 212A, 212C and a dielectric layer 224B in the trench 212B simultaneously. The oxidation process includes oxidizing the sidewalls 212A-S of the upper portion of the trench 212A and the surface portion of the upper portion 220AR-1 of the conductive material 220AR (FIG. 11) to form the gate dielectric layer 224A and the electrode 220F1 in the trench 212A. The top surface 220FIT of the electrode 220F1 may be aligned with the top surface 200T of the epitaxial layer 200 (the top surfaces 220FIT and 200T are coplanar).

The oxidation process also includes oxidizing the sidewalls 212B-S of the upper portion of the trench 212B and the surface portion of the upper portion 220BR-1 of the conductive material 220BR (FIG. 11) to form the dielectric layer 224B and the electrode 220F2 in the trench 212B. The oxidation process further includes oxidizing the sidewalls 212C-S of the upper portion of the trench 212C and the surface portion of the upper portion 220CR-1 of the conductive material 220CR (FIG. 11) to form the dielectric layer 224C and the electrode 220F3 in the trench 212C. The shielding dielectric layers 216AR, 216BR, 216CR surround the lower portions of the conductive materials 220AR, 220BR, 220CR, so the lower portions of the conductive materials 220AR, 220BR, 220CR will not become oxidized. When the gate dielectric layer 224A, the dielectric layer 224B, the gate dielectric layer 224C, and the shielding dielectric layers 216AR, 216BR, and 216CR all include silicon oxide, there is no obvious interface between the gate dielectric layers 224A, 224C and the shielding dielectric layer 216AR, 216CR (or between the dielectric layer 224B and shielding dielectric layer 216BR). Furthermore, the gate dielectric layer 224A, the dielectric layer 224B and the gate dielectric layer 224C may extend to cover the top surface 200T of the epitaxial layer 200 in the first region 400, the second region 410 and the third region 420. The oxidation process may also include forming an oxide layer (not shown) on the oxide layer 222DR in the fourth region 430.

In some embodiments, the gate dielectric layer 224A does not fill up the trench 212A. Furthermore, the gate dielectric layer 224A includes a gate dielectric layer 224A-1 conformally formed on the sidewalls 212A-S (FIG. 11) of the upper portion of the trench 212A, and a gate dielectric layer 224A-2 surrounding the upper portion of the electrode 220F1. Similarly, the dielectric layer 224B does not fill up the trench 212B. Furthermore, the dielectric layer 224B includes a dielectric layer 224B-1 conformally formed on the sidewalls 212B-S (FIG. 11) of the upper portion of the trench 212B, and a dielectric layer 224B-2 surrounding the upper portion of the electrode 220F2. Similarly, the dielectric layer 224C does not fill up the trench 212C. Furthermore, the gate dielectric layer 224C includes a gate dielectric layer 224C-1 conformally formed on the sidewalls 212C-S (FIG. 11) of the upper portion of the trench 212C, and a gate dielectric layer 224C-2 surrounding the upper portion of the electrode 220F3. In some embodiments, the thicknesses of the gate dielectric layer 224A-1, the dielectric layer 224B-1, and the gate dielectric layer 224C-1 are less than the thicknesses of the shielding dielectric layers 216AR, 216BR, and 216CR. Compared to the gate dielectric layer 224A-1, the dielectric layer 224B-1, and the gate dielectric layer 224C-1, which are formed by oxidizing the epitaxial layer 200 formed of silicon carbide, for example, the gate dielectric layer 224A-2, the dielectric layer 224A-2, the electrical layer 224B-2 and the gate dielectric layer 224C-2 are formed by oxidizing the conductive materials 220AR, 220BR, and 220CR (FIG. 11) formed of polycrystalline silicon, for example. Therefore, the conductive materials 220AR, 220BR, and 220CR may have a thicker thickness.

After performing the oxidation process, the unoxidized conductive material 220AR, 220BR, and 220CR in the trenches 212A, 212B, and 212C may form the electrodes 220F1, 220F2, and 220F3 respectively. In addition, the unoxidized conductive material 220DR in the trench 212D may form the electrode 220F4. In some embodiment, the electrodes 220F1, 220F2, 220F3, 220F4 extend along the direction 320. In the direction 300, since the gate dielectric layer 224A-2, the dielectric layer 224B-2, and the gate dielectric layer 224C-2 have a thickness thicker than the gate dielectric layer 224A-1, the dielectric layer 224B-1, and the gate dielectric layer 224C-1, the width W1 of the upper portion of the electrode 220F1 (i.e., the upper portion 220AR-1 of the unoxidized conductive material 220A) may be smaller than the width W2 of the lower portion of the electrode 220F1 (i.e., the portion surrounded by shielding dielectric layer 216AR). Similarly, in the direction 300, the width W3 of the upper portion of the electrode 220F2 (i.e., the upper portion 220BR-1 of the unoxidized conductive material 220B) may be smaller than the width W4 of the lower portion of the electrode 220F2 (i.e., the portion surrounded by shielding dielectric layer 216BR). The width W5 of the upper portion of the electrode 220F3 (i.e. the upper portion 220CR-1 of the unoxidized conductive material 220C) may be smaller than the width W6 of the lower portion of the electrode 220F3 (i.e. the portion surrounded by the shielding dielectric layer 216CR). In some embodiments, the widths W1, W3, and W5 may be equal to each other. In addition, the widths W2, W4, and W6 may be equal to each other. Furthermore, in the direction 300, the electrode 220F4 has a uniform width W7. In some embodiments, the width W7 may be equal to the widths W1, W3, and W5.

In some embodiments, the above-mentioned oxidation process may be thermal oxidation or another suitable process. In some embodiments, the gate dielectric layer 224A, the dielectric layer 224B, and the gate dielectric layers 224C are formed by an oxidation process and a subsequent deposition process. In some embodiments, the deposition process may be low pressure chemical vapor deposition (LPCVD) or another suitable process.

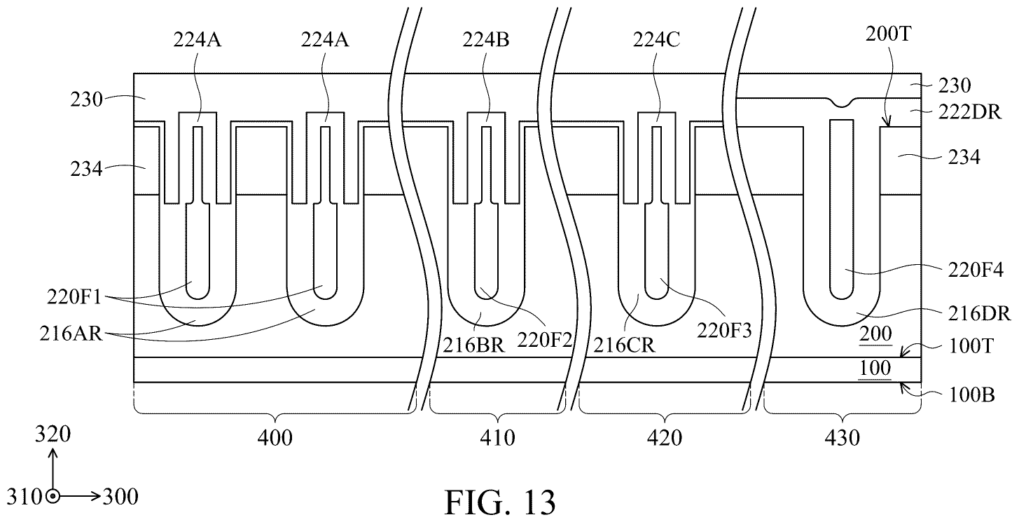

Next, as shown in FIG. 13, a deposition process and a subsequent planarization process may be performed to entirely form an electrode material 230 on the epitaxial layer 200. The electrode material 230 may cover the gate dielectric layer 224A in the first region 400, the dielectric layer 224B in the second region 410, the gate dielectric layers 224C in the third region 420, and the oxide layer 222DR in the fourth region 430. Furthermore, the electrode material 230 may fill the trenches 212A, 212B and 212C (FIG. 12). In some embodiments, the electrode material 230, the electrodes 220F1, 220F2, 220F3 and 220F4 may include the same material, such as polysilicon. In some embodiments, the deposition process may include metal organic chemical vapor deposition (MOCVD), sputtering, resistive thermal evaporation, electron beam evaporation, or another suitable deposition process. In some embodiments, the planarization process includes a chemical mechanical polishing (CMP) process.

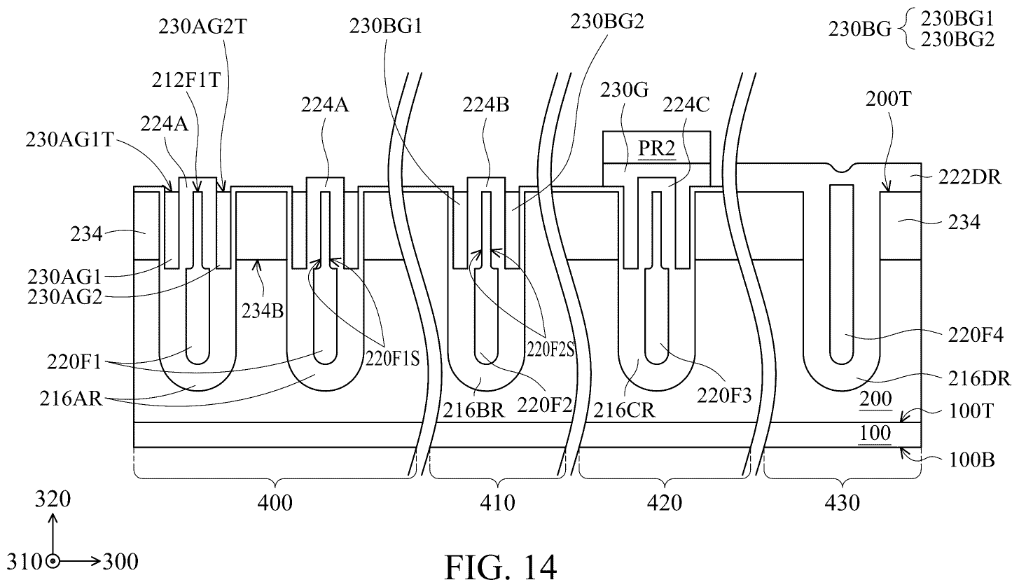

Next, as shown in FIG. 14, a patterning process may be performed to remove a portion of the electrode material 230 above the epitaxial layer 200 in the first region 400, the second region 410 and the fourth region 430 (FIG. 13). The patterning process may include a photolithography process and a subsequent selective etching process. The photolithography process may form a mask pattern PR2 such as a photoresist pattern above the epitaxial layer 200 in the third region 420. The mask pattern PR2 may cover the electrode material 230 in the third region 420 and expose the electrode material 230 in the first region 400, the second region 410 and the fourth region 430. Next, a selective etching process may be performed to remove the electrode material 230 located on the top surface 200T of the epitaxial layer 200 in the first region 400 and on the upper portion of the trench 212A close to the top surface 200T of the epitaxial layer 200 to form the gate electrodes 230AG1 and 230AG2 on the opposite sidewalls 220F1S of the electrode 220F1 in the trench 212A. The gate electrodes 230AG1 and 230AG2 are separated from each other in the direction 300 and extend along the direction 320. Moreover, the selective etching process may simultaneously remove the electrode material 230 located on the top surface 200T of the epitaxial layer 200 in the second region 410 and on the upper portion of the trench 212B close to the top surface 200T of the epitaxial layer 200 to form the conductive features 230BG1 and 230BG2 on the opposite sidewalls 220F2S of the electrode 220F2. The conductive features 230BG1 and 230BG2 are separated from each other in the direction 300 and extend along the direction 320. The conductive features 230BG1 and 230BG2 may collectively form a separated conductive structure 230BG. As shown in FIG. 14, the gate electrodes 230AG1, 230AG2, the conductive features 230BG1, and the conductive features 230BG2 may extend to below the bottom surface 234B of the well region 234 along the direction 320. In some embodiments, the gate electrodes 230AG1 and 230AG2 may fill up the trench 212A, and the conductive features 230BG1 and 230BG2 may fill up the trench 212B. In some embodiments, the top surface 230AGIT of the gate electrode 230AG1, the top surface 230AG2T of the gate electrode 230AG2, the top surface 230BGIT of the conductive feature 230BG1, the top surface 230BG2T of the conductive feature 230BG2, and the top surface 220FIT of the electrode 220F1 may be all aligned with the top surface 220T of the epitaxial layer 200.

As shown in FIG. 14, the selective etching process may also remove the electrode material 230 on the oxide layer 222DR in the fourth region 430. After performing the selective etching process, the gate electrode 230G may be formed above the epitaxial layer 200 in the third region 420 and in the trench 212C (FIG. 12). In some embodiments, the gate electrode 230G may fill up the remaining space of the trench 212B and extend to cover the electrode 220F3 and the epitaxial layer 200 outside the trench 212C. Since the electrode material 230 is formed of a material that is different from the gate dielectric layer 224A, the dielectric layer 224B, the gate dielectric layer 224C and the oxide layer 222DR, the gate dielectric layer 224A, the dielectric layer 224B, the gate dielectric layer 224C and the oxide layer 222DR will not be removed by the above selective etching process. In some embodiments, the selective etching process includes dry etching. After forming the gate electrodes 230AG1, 230AG2, the conductive features 230BG1 and 230BG2, and the gate electrode 230G, the mask pattern PR2 is removed.

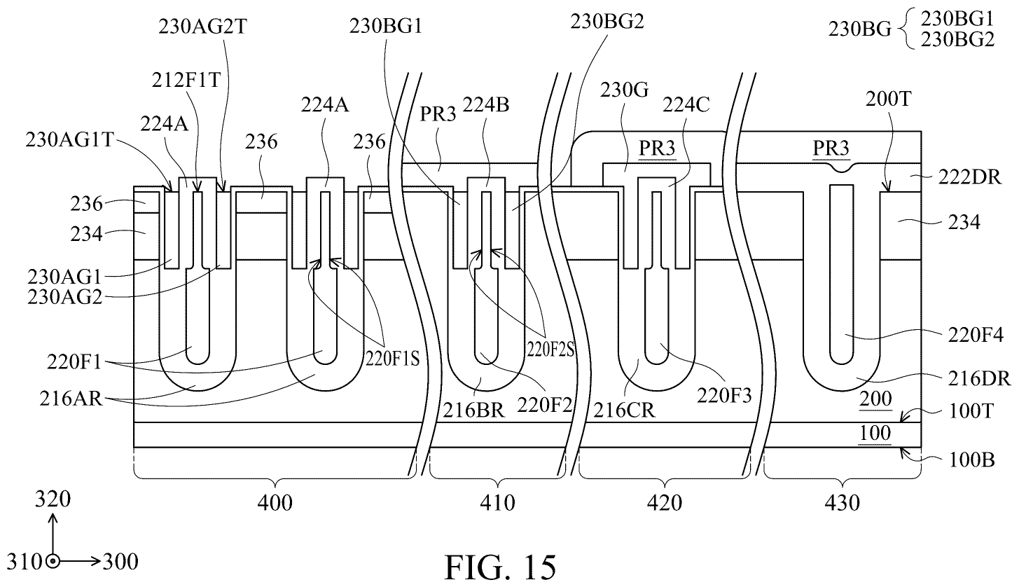

The formations of the source region 236 and the pick-up doped region 238 will be described with reference to FIGS. 15 and 16 respectively. Furthermore, the formation positions of the source region 236 and the pick-up doped region 238 in the first region 400 will be described with reference to FIG. 23. In order to illustrate the arrangement of the source region 236 and the pick-up doped region 238, the gate dielectric layer 224A-1 covering the top surface 200T of the epitaxial layer 200 is not shown in FIG. 23. FIGS. 15 and 16 illustrate cross-sectional views of the intermediate structure of the semiconductor device 500 at different positions in the direction 310 in accordance with some embodiments of the disclosure. FIG. 23 is a schematic top view of an intermediate stage of forming the semiconductor device 500 of FIG. 1 in accordance with some embodiments of the disclosure, showing the arrangement of the source region 236 and the pick-up doped region 238 above the well region 234. The first region 400 shown in FIGS. 15 and 16 may respectively correspond to the cross-sectional positions taken along the line A-A′ and the line B-B′ in FIG. 23 to illustrate the formation of the source regions 236 and the pick-up doped regions 238 located in the epitaxial layer 200 in the first region 400 and alternately arranged in the direction 310.

As shown in FIG. 15, a photolithography process may be performed to form a mask pattern PR3 such as a photoresist pattern above the epitaxial layer 200 in the second region 410, the third region 420 and the fourth region 430, exposing the predetermined formation region of the source region 236 in the first region 400 (corresponding to the formation region of the source region 236 in FIG. 23). Next, an ion implantation process is performed to form a source region 236 of the first conductivity type (for example, an N-type source region 236) on the well region 234 in the first region 400. After forming the source region 236, the mask pattern PR3 is removed.

As shown in FIG. 16, another photolithography process may be performed to form a mask pattern PR4 such as a photoresist pattern above the epitaxial layer 200 in the second region 410 the third region 420 and the fourth region 430, exposing the predetermined formation region of the pick-up doped region 238 in the first region 400 (corresponding to the formation region of the pick-up doped region 238 in FIG. 23). It is noted that the predetermined formation regions of the source region 236 and the pick-up doped region 238 are respectively located in different regions of the epitaxial layer 200 that are alternately arranged along the direction 310 (FIG. 23). Next, an ion implantation process is performed to form a pick-up doped region 238 of the second conductivity type (for example, a P-type pick-up doped region 238) on the well region 234 in the first region 400. After forming the pick-up doped region 238, the mask pattern PR4 is removed.

In some embodiments, the source region 236 and the pick-up doped region 238 are disposed in the epitaxial layer 200 adjacent to the trench 212A. Furthermore, the source region 236 and the pick-up doped region 238 are respectively disposed in the epitaxial layer 200 between two adjacent pairs of the gate electrodes 230AG1 and 230AG2 along the direction 300. In other words, the source region 236 and the pick-up doped region 238 are respectively disposed in the mesa region 400M. In the direction 300, there is no other doped region between the opposite sidewalls of each of the source region 236 and the pick-up doped region 238 and the two adjacent gate electrodes 230AG1 and 230AG2 of the two adjacent pairs of the gate electrodes 230AG1 and 230AG2 that are close to each other.

In some embodiments, the process sequences shown in FIGS. 15 and 16 may be interchanged. That is to say, the pick-up doped region 238 may be formed first, and then the source region 236 may be formed.

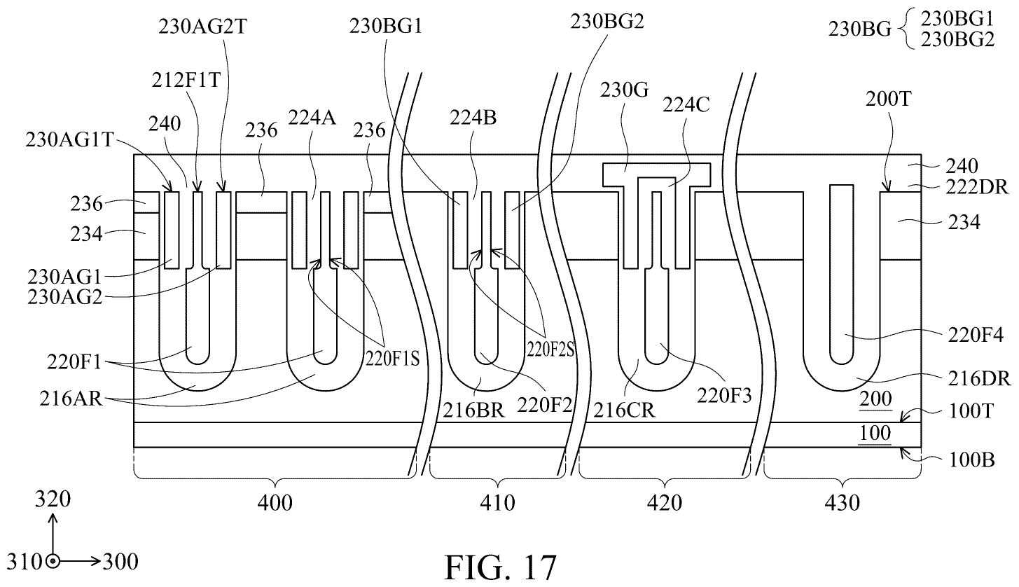

Next, as shown in FIG. 17, a deposition process and a subsequent planarization process may be performed to entirely form an interlayer dielectric layer 240 on the epitaxial layer 200. The interlayer dielectric layer 240 may cover the gate electrode 230AG1, the gate electrode 230AG2, the conductive feature 230BG1, the conductive feature 230BG2, the gate electrode 230G, the gate dielectric layer 224A, the dielectric layer 224B, the gate dielectric layer 224C and the oxide layer 222DR. When the gate dielectric layer 224A, the dielectric layer 224B, the gate dielectric layer 224C and the oxide layer 222DR and the interlayer dielectric layer 240 all include silicon oxide, there are no obvious interfaces between the interlayer dielectric layer 240 and the gate dielectric layer 224A, the dielectric layer 224B, the gate dielectric layer 224C and the oxide layer 222DR. In some embodiments, the planarization process includes a chemical mechanical polishing (CMP) process.

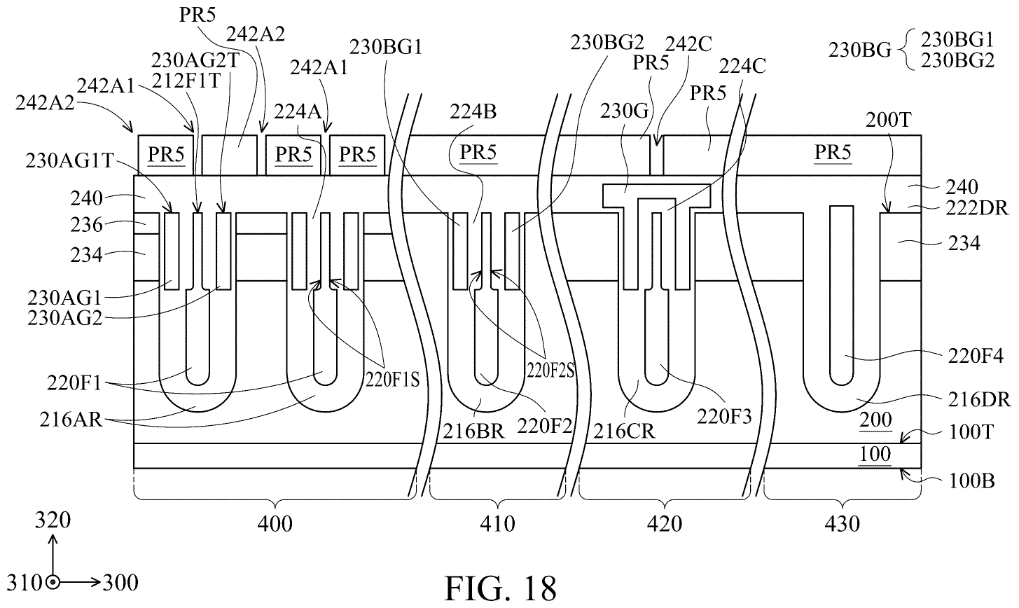

Next, as shown in FIG. 18, a photolithography process may be performed to form a mask pattern PR5 such as a photoresist pattern on the epitaxial layer 200. The mask pattern PR5 has an opening 242A1 located directly above the electrode 220F1, an opening 242A2 located directly above the source region 236 and the pick-up doped region 238, and an opening 242C located directly above the gate electrode 230G. Moreover, the mask pattern PR5 completely covers the epitaxial layer 200 and the interlayer dielectric layer 240 in the second region 410 and the fourth region 430.

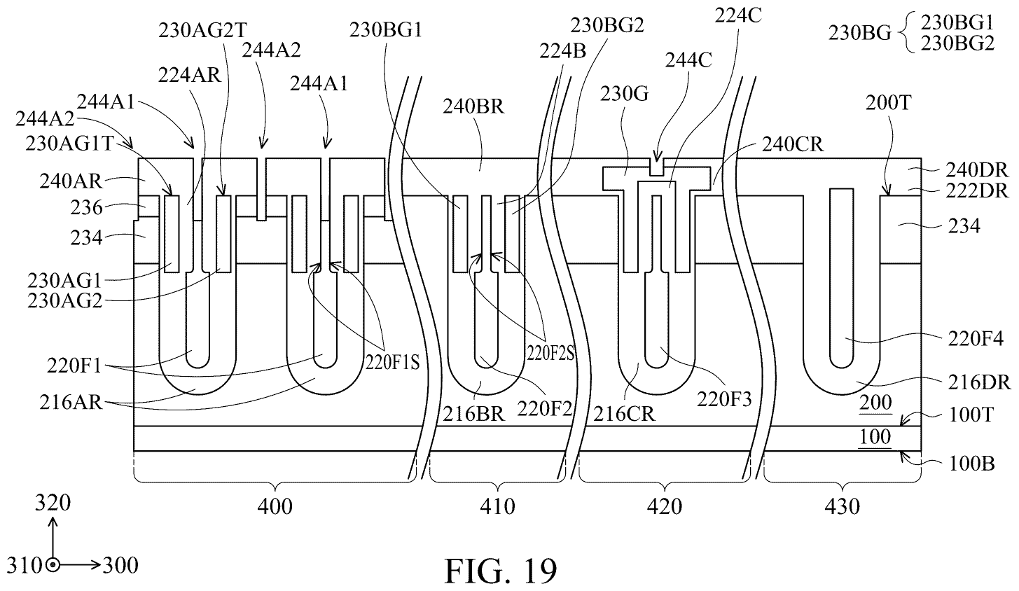

Next, as shown in FIG. 19, an etching process may be performed to remove the interlayer dielectric layer 240 and the gate dielectric layer 224A, the electrode 220F1 and a portion of the epitaxial layer 200 located under the interlayer dielectric layer 240 and exposed from the openings 242A1 and 242A2 of the mask pattern PR5 (FIG. 18) to form an opening (a contact hole) 244A1 exposing the electrode 220F1 and openings (contact holes) 244A2 exposing the well region 234, the source electrode region 236 and the pick-up doped region 238 in the interlayer dielectric layer 240 in the first region 400. The etching process simultaneously removes the interlayer dielectric layer 240 and a portion of the gate electrode 230G thereunder exposed from the opening 242C (FIG. 18) of the mask pattern PR5, so as to form an opening (a contact hole) 244C in a portion of the interlayer dielectric layer 240 directly above the gate electrode 230G of the third region 420. Therefore, the gate electrode 230G is exposed from the opening 244C. In some embodiments, the etching process includes dry etching. After performing the etching process, the remaining interlayer dielectric layer 240 in the first region 400 is denoted as the interlayer dielectric layer 240AR, and the remaining gate dielectric layer 224A in the first region 400 is denoted as the gate dielectric layer 224AR. The gate dielectric layer 224AR and the gate electrodes 230AG1 and 230AG2 may collectively form the split gate structure 230AG. Moreover, the remaining portions of the interlayer dielectric layer 240 in the second region 410, the third region 420, and the fourth region 430 are respectively denoted as the interlayer dielectric layer 240BR, the interlayer dielectric layer 240CR, and the interlayer dielectric layer 240DR. After forming the interlayer dielectric layer 240AR, the gate dielectric layer 224AR, the interlayer dielectric layer 240BR, the interlayer dielectric layer 240CR, and the interlayer dielectric layer 240DR, the mask pattern PR5 is removed.

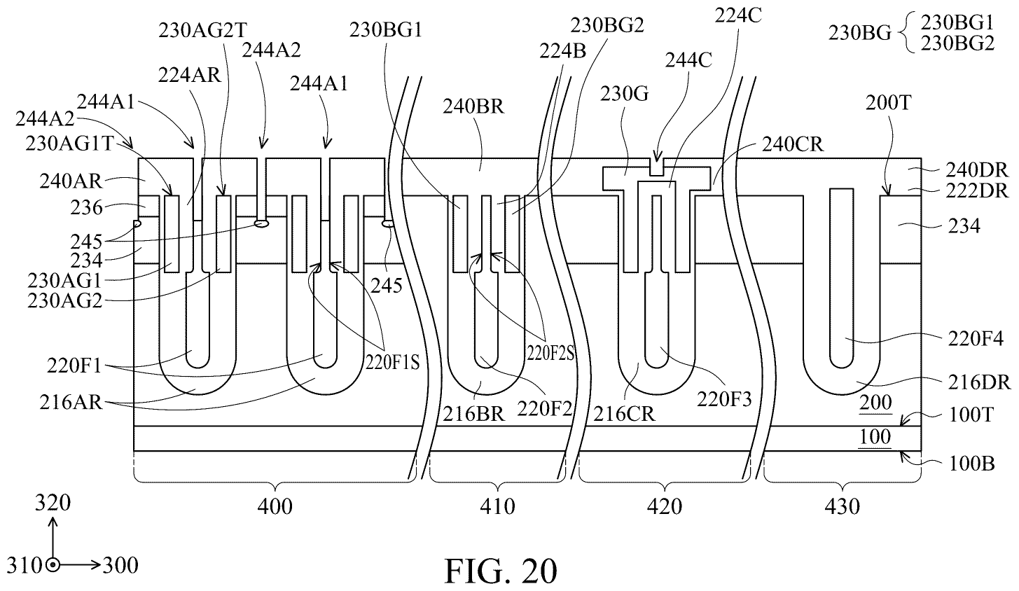

Next, as shown in FIG. 20, an ion implantation process may be performed to form a contact doped region 245 in the epitaxial layer 200 below the opening (the contact hole) 244A2. The contact doped region 245 and the well region 234 have the same conductivity type. For example, the contact doped region 245 may serve as a P-type contact doped region 245. Furthermore, the doping concentration of the contact doped region 245 is greater than the doping concentration of the well region 234. For example, when the well region 234 is a P-type well region 234, the contact doped region 245 is a P-type heavily doped (P+) contact doped region 245 to serve as a pick-up doped region of the well region 234. After performing the foregoing ion implantation process, an annealing process may be performed to activate the dopants in the well region 234, the source region 236, the pick-up doped region 238 and the contact doped region 245. In some embodiments, the annealing process includes laser annealing, rapid thermal annealing (RTA), other suitable annealing processes, or a combination thereof.

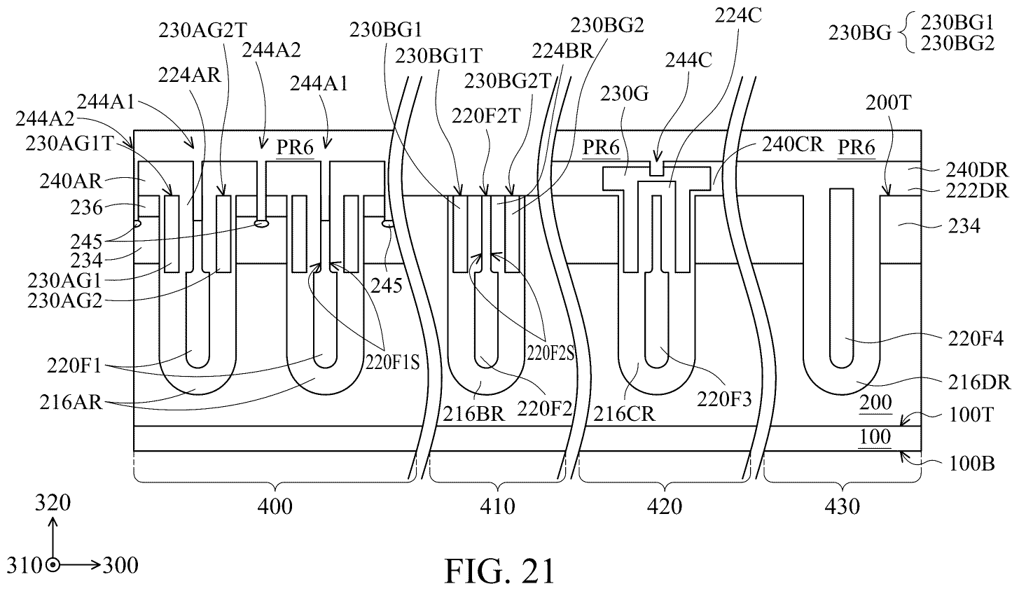

Next, as shown in FIG. 21, a photolithography process may be performed to form a mask pattern PR6, such as a photoresist pattern, on the epitaxial layer 200 in the first region 400, the third region 420, and the fourth region 430. The mask pattern PR6 may fill the openings (the contact holes) 244A1, 244A2, and 244C, and exposes the interlayer dielectric layer 240BR (FIG. 20) in the second region 410. Next, an etching process is performed to remove the interlayer dielectric layer 240BR and the dielectric layer 224B on the top surface 200T of the epitaxial layer 200 in the second region 410 (FIG. 20). After performing the aforementioned processes, the remaining dielectric layer 224B is denoted as a dielectric layer 224BR. After performing the aforementioned processes, the electrode 220F2 and at least one of the conductive feature 230BG1 and the conductive feature 230BG2 are exposed from the remaining interlayer dielectric layers 240AR, 240CR, and 240DR. In some embodiments as shown in FIG. 21, the top surface 220F2T of the electrode 220F2, the top surface 230BGIT of the conductive feature 230BG1, and the top surface 230BG2T of the conductive feature 230BG2 are exposed from the remaining interlayer dielectric layers 240AR, 240CR, 240DR. In some embodiments as shown in FIG. 1B, the top surface 220F2T of the electrode 220F2 and the top surface 230BG2T of the conductive feature 230BG2 closest to the first region 400 are exposed from the remaining interlayer dielectric layers 240AR, 240CR, 240DR. After removing the interlayer dielectric layer 240B (FIG. 20) on the top surface 200T of the epitaxial layer 200 in the second region 410, the mask pattern PR6 is removed.

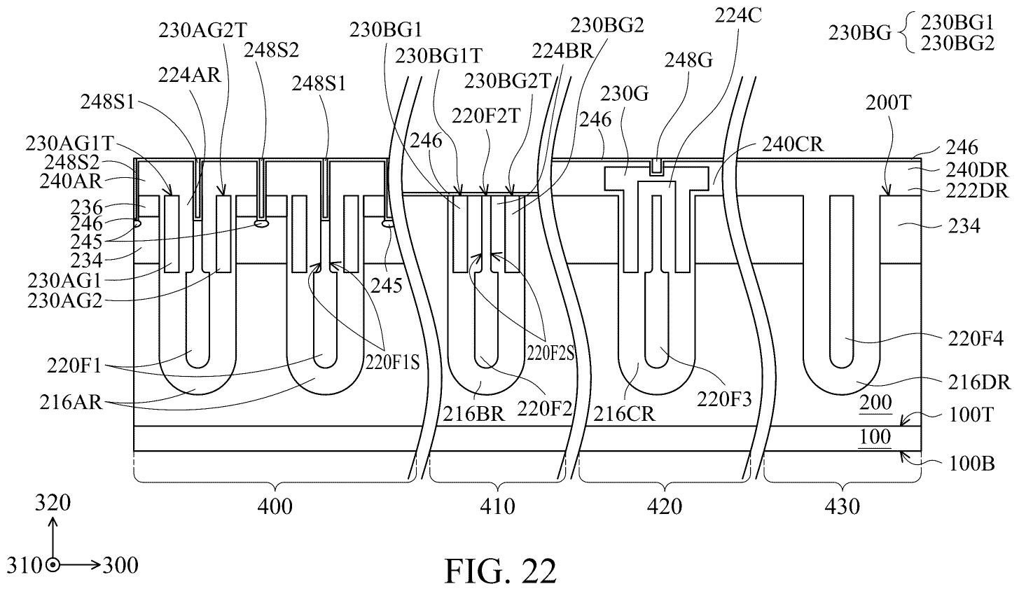

Next, as shown in FIG. 22, a deposition process may be performed to form a contact barrier layer 246 on the interlayer dielectric layers 240AR, 240CR, and 240DR and on the top surface 200T of the epitaxial layer 200 in the second region 410. In addition, the contact barrier layer 246 is conformably deposited in the openings (the contact holes) 244A1, 244A2, and 244C (FIG. 20). The contact barrier layer 246 in the second region 410 is in direct contact with the separated conductive structure 230BG and the electrode 220F2 that are not covered by the interlayer dielectric layer 240AR. In some embodiments as shown in FIG. 22, the contact barrier layer 246 in the second region 410 is in direct contact with the top surface 220F2T of the electrode 220F2, the top surface 230BGIT of the conductive feature 230BG1, and the top surface 230BG2T of the conductive feature 230BG2. In some embodiments as shown in FIG. 1B, the contact barrier layer 246 in the second region 410 is in direct contact with the top surface 220F2T of the electrode 220F2 and the top surface 230BG2T of the conductive feature 230BG2 closest to the first region 400.

Next, as shown in FIG. 22, a contact conductive layer (not shown) is deposited above the contact barrier layer 246. The contact conductive layer may fill up the remaining space in the openings (the contact holes) 244A1, 244A2, and 244C. Next, a removal process (such as an etching process or a planarization process) is performed to remove the excess portion of the contact conductive layer on the interlayer dielectric layers 240AR, 240CR, 240DR and above the top surface 200T of the epitaxial layer 200 in the second region 410, so as to form the contact conductive layer 248S1, the contact conductive layer 248S2, and the contact conductive layer 248G in the openings (the contact holes) 244A1, 244A2, and 244C. The contact conductive layer 248S1, the contact conductive layer 248S2, and the contact conductive layer 248G may fill up the remaining spaces of the openings (the contact holes) 244A1, 244A2, and 244C. The contact barrier layer 246 in the second region 410 is not covered by the contact conductive layer. Furthermore, the contact barrier layer 246 is not removed by the removal process.

Next, as shown in FIGS. 1A and 1B, a deposition process and a subsequent patterning process may be performed to form the source metal layer 254S on the epitaxial layer 200 in the first region 400 and the second region 410, and form the gate metal layer 254G on the epitaxial layer 200 in the third region 420. The deposition process may entirely form a metal layer (not shown), which covers and is physically connected to the contact conductive layer 248S1, the contact conductive layer 248S2, and the contact conductive layer 248G. In addition to removing the metal layer in the fourth region 430, the above patterning process also includes removing the contact barrier layer 246 in the fourth region 430 to form the contact barrier layer 246S on the epitaxial layer 200 in the first region 400 and the second region 410, and form a contact barrier layer 246G on the epitaxial layer 200 in the third region 420. The contact barrier layer 246S and contact barrier layer 246G are spaced apart from each other. The source metal layer 254S is in direct contact with the contact barrier layer 246S in the first region 400 and the second region 410. The gate metal layer 254G is in direct contact with the contact barrier layer 246G in the third region 420.

During the formation of the source metal layer 254S, the gate metal layer 254G, the contact barrier layer 246S and the contact barrier layer 246G, the source contact 250S1 (including the contact barrier layer 246S and the contact conductive layer 248S1) is formed on the electrode 220F1 in the first region 400, and the source contact 250S2 (including the contact barrier layer 246S and the contact conductive layer 248S2) is formed on the well region 234, the source region 236, and the pick-up doped region 238 in the first region 400. In addition, the gate contact 250G (including the contact barrier layer 246G and the contact conductive layer 248G) is formed on the gate electrode 230G in the third region 420 simultaneously.

As shown in FIGS. 1A and 1B, the source metal layer 254S is continuously distributed on the epitaxial layer 200 in the first region 400 and the second region 410. The source metal layer 254S covers and is electrically connected to the source contacts 250S1 and 250S2. Furthermore, the source metal layer 254S covers and is electrically connected to the separated conductive structure 230BG and the electrode 220F2 that are not covered by the interlayer dielectric layer 240AR. In some embodiments shown in FIGS. 1A and 1B, the source metal layer 254S in the second region 410 covers and is electrically connected to the top surface 220F2T of the electrode 220F2 and the top surface 230BG2T of the conductive feature 230BG2 closest to the first region 400. In addition, the source metal layer 254S in the second region 410 covers and is electrically connected to the separated conductive structure 230BG (including the conductive features 230BG1, 230BG2) and the electrode 220F2 away from the first region 400. Furthermore, the source metal layer 254S is in direct contact with the contact barrier layer 246S in the first region 400 and the second region 410. As shown in FIG. 1B, the source metal layer 254S located and the contact barrier layer 246S thereunder in the second region 410, and the epitaxial layer (the drift region) 200 between two adjacent pairs of separated conductive structures 230BG may collectively form a Schottky diode.

As shown in FIGS. 1A and 1B, the gate metal layer 254G covers and is electrically connected to the gate contact 250G. Moreover, the gate metal layer 254G is in direct contact with the contact barrier layer 246G in the third region 420.

In some embodiments, the deposition process for forming the source metal layer 254S and the gate metal layer 254G may include a physical vapor deposition process, a chemical vapor deposition process, other suitable processes, or a combination of thereof.

Subsequent processes may be further performed to form a drain contact (not shown) on the bottom surface 100B of the silicon carbide substrate 100. The drain contact may be electrically connected to the silicon carbide substrate 100. After performing the aforementioned processes, the semiconductor device 500 is formed.

Embodiments provide a semiconductor device and a method for forming the same. The semiconductor device includes a shielded gate trench metal-oxide-semiconductor field-effect transistor (SGT MOSFET) unit formed in a cell region (e.g., the first region 400) of the epitaxial layer. The shielded gate trench metal-oxide-semiconductor field-effect transistor unit has a split gate structure. The two gates of the split gate structure (for example, the gate electrodes 230AG1 and 230AG2) are formed on opposite sidewalls of the electrode functioning as a field plate (which may also be called a source electrode, such as the first electrode 220F1). The split gate structure may further reduce the overall gate-to-drain capacitance (C_{gd}) and feedback capacitance (Cᵣₛₛ=C_{gd}) to improve overall power conversion efficiency of the shielded gate trench metal-oxide-semiconductor field-effect transistor (SGT MOSFET). The source electrode may reduce the gate-to-drain capacitance (C_{gd}) to improve the switching characteristics of the semiconductor device. In addition, the source electrode may result in a relatively uniform distribution of the electric field of the gate dielectric layer close to the bottom of the gate electrode and an increased breakdown voltage. Therefore, the reliability of the gate dielectric layer is improved. Furthermore, through the arrangement of the source electrode, the doping concentration of the epitaxial layer (the drift region) can be further increased in to reduce the on-resistance (Rₒₙₛₚ) of the shielded gate trench metal-oxide-semiconductor field-effect transistor unit.

The semiconductor device in accordance with some embodiments of the disclosure further includes a Schottky diode formed in a trench MOS barrier Schottky diode region (e.g., the second region 410). The Schottky diode is composed of an epitaxial layer (e.g., the epitaxial layer 200), a contact barrier layer (e.g., the contact barrier layer 246S), and a source metal layer (e.g., the source metal layer 254S). The Schottky diode may be connected in parallel with the shielded gate trench metal-oxide-semiconductor field-effect transistor unit to disable the body diode. Therefore, the on-resistance and the power losses of the semiconductor device can be reduced, and the switching characteristics of the semiconductor device can be improved.

In some embodiments, the Schottky diode is sandwiched between two adjacent pairs of trench-type separated conductive structures (such as the separated conductive structure 230BG), and thus can be called a trench MOS barrier Schottky (TMBS) diode. The reverse leakage current of the Schottky diode in accordance with some embodiments of the disclosure can be clamped by the trench-type separated conductive structure, resulting in a lower leakage current. In some embodiments, two conductive features (for example, the conductive features 230BG1 and 230BG2) of the trench-type separated conductive structure are formed on opposite sidewalls of another electrode, functioning as a field plate (which may also be called a source electrode, such as the electrode 220F2). In some embodiments, because the other source electrode inserted into the two conductive features also has a function of a field plate, such that the distribution of the electric field in the epitaxial layer (the drift region) of the Schottky diode is relatively uniform. Therefore, the doping concentration of the epitaxial layer (the drift region) can be further increased in order to reduce the forward voltage drop (VF) of the trench MOS barrier Schottky diode. Therefore, the Schottky diode in accordance with some embodiments of the disclosure can not only improve the switching characteristics of the semiconductor device, but also further reduce the forward voltage drop (VF) and reverse leakage current of the Schottky diode.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a silicon carbide substrate, wherein the silicon carbide substrate has a first region and a first conductivity type;
an epitaxial layer disposed on a top surface of the silicon carbide substrate, wherein the epitaxial layer has the first conductivity type;
a first electrode disposed in the epitaxial layer in the first region and extending in a first direction;
a separated conductive structure disposed in the epitaxial layer in the first region, wherein the separated conductive structure comprises:
a first conductive feature and a second conductive feature separated from each other and located on opposite sidewalls of the first electrode; and
a source metal layer disposed on the epitaxial layer in the first region, wherein the source metal layer covers and is electrically connected to the first conductive feature, the second conductive feature and the first electrode.

2. The semiconductor device as claimed in claim 1, further comprising:
a contact barrier layer disposed on the epitaxial layer in the first region, wherein the contact barrier layer is in direct contact with the source metal layer and at least one of the first electrode, the first conductive feature and the second conductive feature.

3. The semiconductor device as claimed in claim 1, wherein the silicon carbide substrate has a second region, and the semiconductor device further comprises:
a well region located in the epitaxial layer in the second region, wherein the well region has a second conductivity type;
a second electrode disposed in the epitaxial layer in the second region and extending along the first direction;
a split gate structure disposed in the epitaxial layer in the second region, wherein the split gate structure comprises:
a first gate and a second gate separated from each other and located on opposite sidewalls of the second electrode;
an interlayer dielectric layer disposed on the epitaxial layer in the second region; and
source contacts passing through the interlayer dielectric layer in the second region and extending into the second electrode and the well region, wherein the source metal layer covers and is electrically connected the source contacts.

4. The semiconductor device as claimed in claim 3, wherein the first electrode is exposed from the interlayer dielectric layer.

5. The semiconductor device as claimed in claim 3, wherein at least one of the first conductive feature and the second conductive feature is exposed from the interlayer dielectric layer.

6. The semiconductor device as claimed in claim 3, further comprising:
a first dielectric layer disposed in the epitaxial layer in the first region and surrounding the first conductive feature and the second conductive feature, wherein the first electrode, the first conductive feature and the second conductive feature are exposed from a top surface of the first dielectric layer,
wherein the split gate structure further comprises:
a first gate dielectric layer disposed in the epitaxial layer in the second region and surrounding the first gate and the second gate, wherein the interlayer dielectric layer covers the first gate dielectric electrical layer.

7. The semiconductor device as claimed in claim 6, wherein a sidewall of the interlayer dielectric layer is located on the first dielectric layer close to the first electrode.

8. The semiconductor device as claimed in claim 3, further comprising:
source regions and pick-up doped regions located on the well region in the second region and close to a top surface of the epitaxial layer, wherein the source regions and the pick-up doped regions are alternately arranged along a third direction and having opposite conductivity types,
wherein the source contacts are connect to the source regions and the pick-up doped regions.

9. The semiconductor device as claimed in claim 8, wherein the interlayer dielectric layer covers the source regions and the pick-up doped regions.

10. The semiconductor device as claimed in claim 3, wherein the silicon carbide substrate has a third region and a fourth region, and the semiconductor device further comprises:
a third electrode disposed in the epitaxial layer in the third region and extending along the first direction, wherein the third electrode is electrically connected to the source contacts;
a third gate disposed in the epitaxial layer in the third region and connected to the split gate structure, wherein the third gate extends from opposite sidewalls of the third electrode to cover a third electrode top surface of the third electrode and a top surface of the epitaxial layer;
a gate contact extending from above the epitaxial layer in the third region into the third gate and electrically connected to the third gate;
a gate metal layer disposed on the epitaxial layer in the third region, wherein the gate metal layer covers and is electrically connected to the gate contact; and
a fourth electrode disposed in the epitaxial layer in the fourth region and extending along the first direction, wherein the fourth electrode is electrically connected to the source contacts,
wherein the well region is located in the epitaxial layer in the third region and the fourth region, and the interlayer dielectric layer covers the third electrode and the fourth electrode.

11. A method for forming a semiconductor device, comprising:
providing a silicon carbide substrate, wherein the silicon carbide substrate has a first region and a first conductivity type;
growing an epitaxial layer on a top surface of the silicon carbide substrate, wherein the epitaxial layer has the first conductivity type;
forming a first trench in the epitaxial layer in the first region along a first direction;
forming a first electrode in the first trench, wherein the first electrode extends in the first direction;
forming a separated conductive structure on opposite sidewalls of the first electrode, wherein the separated conductive structure comprises a first conductive feature and a second conductive feature that are separated from each other;
entirely forming an interlayer dielectric layer;
removing the interlayer dielectric layer on a top surface of the epitaxial layer in the first region, so that the first electrode and at least one of the first conductive feature and the second conductive feature are exposed from the remaining interlayer dielectric layer; and
forming a source metal layer on the epitaxial layer in the first region, wherein the source metal layer covers and is electrically connected to the first electrode, the first conductive feature and the second conductive feature.

12. The method for forming a semiconductor device as claimed in claim 11, further comprising:
forming a well region in the epitaxial layer in a second region of the silicon carbide substrate before forming the first trench, wherein the well region has a second conductivity type;
forming a second trench in the epitaxial layer in the second region along the first direction during the formation of the first trench;
forming a second electrode in the second trench during the formation of the first electrode;
forming a first gate and a second gate on opposite sidewalls of the second electrode during the formation of the separated conductive structure; and
forming source regions and pick-up doped regions on the well region in the second region, wherein the source regions and the pick-up doped regions are alternately arranged along a third direction and have opposite conductivity types;
performing a patterning process on the interlayer dielectric layer to form first openings in the interlayer dielectric layer in the second region to respectively expose the second electrode, the source regions and the pick-up doped regions; and
forming source contacts in the first openings during the formation of the source metal layer.

13. The method for forming a semiconductor device as claimed in claim 12,
wherein the patterning process is performed before the removal of the interlayer dielectric layer on the top surface of the epitaxial layer in the first region.

14. The method for forming a semiconductor device as claimed in claim 13, further comprising:
forming a third trench and a fourth trench in the epitaxial layer in a third region and a fourth region of the silicon carbide substrate respectively along the first direction during the formation of the first trench;
forming a third electrode and a fourth electrode in the third trench and the fourth trench respectively during the formation of the first electrode;
forming a third gate in the third trench during the formation of the separated conductive structure;
forming a second opening in the interlayer dielectric layer in the third region to expose the third gate during the patterning process; and
forming a gate contact in the second opening before forming the source metal layer.

15. The method for forming a semiconductor device as claimed in claim 14, further comprising:
forming a mask pattern on the epitaxial layer in the second region, the third region and the fourth region after forming the first openings and the second openings, wherein the mask pattern fills the first openings and the second opening; and
removing the mask pattern after the removal of the interlayer dielectric layer on the top surface of the epitaxial layer in the first region.

16. The method for forming a semiconductor device as claimed in claim 14,
wherein forming the source contact and the gate contact comprises:
conformally forming a contact barrier layer on the epitaxial layer and in the first openings and the second openings, wherein the contact barrier layer is in direct contact with the first electrode, the second electrode, the third gate, and at least one of the first conductive feature and the second conductive feature;
forming a contact conductive layer to fill the first openings and the second openings; and
removing the contact barrier layer in the fourth region, wherein the source metal layer is in direct contact with the contact barrier layer in the first region and the second region.

17. The method for forming a semiconductor device as claimed in claim 16,
wherein forming the source metal layer comprises:
entirely forming a metal layer, wherein the metal layer covers and is physically connected to the contact conductive layer; and
removing the metal layer in the fourth region to form the source metal layer on the epitaxial layer in the first region and the second region, and to form a gate metal layer on the epitaxial layer in the third region, wherein the source metal layer is continuously distributed on the epitaxial layer in the first region and the second region.

18. The method for forming a semiconductor device as claimed in claim 14, wherein forming the first electrode, the second electrode, the third electrode and the fourth electrode comprises:
forming a first conductive material, a second conductive material, a third conductive material and a fourth conductive material in the first trench, the second trench, the third trench and the fourth trench, wherein the first conductive material, the second conductive material, the third conductive material and the fourth conductive material comprise the same material;
forming an oxide layer on the fourth conductive material; and
performing an oxidation process to form a first dielectric layer, a first gate dielectric layer and a second gate dielectric layer in the first trench, the second trench and the third trench, wherein the formation of the first dielectric layer, the first gate dielectric layer and the second gate dielectric layer comprises partially oxidizing a first upper portion of the first conductive material, a second upper portion of the second conductive material and a third upper a portion of the third conductive material, and the unoxidized first conductive material, the unoxidized second conductive material, the unoxidized third conductive material and the unoxidized fourth conductive material respectively form the first electrode, the second electrode, the third electrode and the fourth electrode.

19. The method for forming a semiconductor device as claimed in claim 18, further comprising:
entirely forming an electrode material on the epitaxial layer after forming the first electrode, the second electrode, the third electrode and the fourth electrode, wherein the electrode material fills the first trench, the second trench and the third trench; and
performing patterning process to remove a portion of the electrode material above the epitaxial layer in the first region, the second region and the fourth region, so as to form the first conductive feature and the second conductive feature in the first trench, to form the first gate and the second gate in the second trench, and to form the third gate in the third trench.

20. The method for forming a semiconductor device as claimed in claim 18, wherein a sidewall of the interlayer dielectric layer is located on the first dielectric layer close to the first electrode after performing the patterning process.
